(19) United States
(12) Patent Application Publication
(10) Pub. No.: US 2026/0259496 A1
(43) Pub. Date: Sep. 3, 2026

(54) POLY(PHTHALALDEHYDE) DERIVATIVES, COMPOSITIONS INCLUDING THE SAME, AND PATTERN FORMATION METHODS

(71) Applicants: DuPont Electronic Materials International, LLC, Marlborough, MA (US); SK hynix Inc., Icheon-si (KR); Cornell University, Ithaca, NY (US)

(72) Inventors: Rachel Snyder, West Boylston, MA (US); Wenxu Zhang, Wellesley, MA (US); Mingqi Li, Shrewsbury, MA (US); Doris Kang, Shrewsbury, MA (US); George G. Barclay, York, ME (US); Kyung Hee Oh, Icheon, Gyeonggi-do (KR); Jae Hyun Kim, Sungnam, Gyeonggi-do (KR); Chunghyeon Ban, Icheon, Gyeonggi-do (KR); Christopher Kemper Ober, Ithaca, NY (US); Madan Rajendra Biradar, Ithaca, NY (US); Huseyin Cem Kiliclar, Ithaca, NY (US)

(21) Appl. No.: 19/059,917

(22) Filed: Feb. 21, 2025

(51) Int. Cl. G03F 7/039; G03F 7/004; G03F 7/16; G03F 7/20; G03F 7/32; G03F 7/38

(52) U.S. Cl. CPC G03F 7/0392; G03F 7/0045; G03F 7/168; G03F 7/2006; G03F 7/322; G03F 7/38

(57) ABSTRACT

A photoresist composition including a first polymer including a first repeating unit derived from a compound of Formula (1); a second polymer including a first repeating unit comprising an acid-labile group, a base-labile group, a base soluble group, or a combination thereof, wherein the first repeating unit of the second polymer is derived from a monomer comprising an ethylenically unsaturated polymerizable double bond; a photoacid generator; and a solvent,

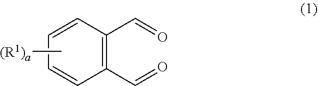

wherein, in Formula (1), each R¹ is a non-hydrogen substituent, each R¹ optionally further includes one or more divalent linking groups as part of their structure, wherein each of the one or more divalent linking groups is independently substituted or unsubstituted, two adjacent R¹ optionally form a ring together, wherein the ring is substituted or unsubstituted, and a is an integer from 1 to 4.

### FIELD

The present invention relates to photoresist compositions that include a poly(phthalaldehyde) (PPA) component. The invention finds applicability in lithographic applications in the semiconductor manufacturing industry.

### BACKGROUND

Photoresist materials are photosensitive compositions typically used for transferring an image to one or more underlying layers such as a metal, semiconductor or dielectric layer disposed on a semiconductor substrate. To increase the integration density of semiconductor devices and allow for the formation of structures having dimensions in the nanometer range, photoresists and photolithography processing tools having high-resolution capabilities have been and continue to be developed.

Chemically amplified photoresists (CAR) are conventionally used for high-resolution processing. Such resists typically employ a polymer having acid-labile groups, a photoacid generator and an acid quenching material. Pattern-wise exposure to activating radiation through a photomask causes the acid generator to form an acid which, during post-exposure baking, causes cleavage of the acid-labile groups in exposed regions of the polymer. Acid quenching materials are often added to the photoresist composition for controlling the diffusion of the acid to unexposed region in order to improve the contrast. The result of the lithographic process is the creation of difference in solubility characteristics between exposed and unexposed regions of the resist in a developer solution. In a positive tone development (PTD) process, exposed regions of the photoresist layer become soluble in the developer and are removed from the substrate surface, whereas unexposed regions, which are insoluble in the developer, remain after development to form a positive image. The resulting relief image permits selective processing of the substrate.

Extreme ultraviolet lithography (EUVL) is an optical lithography technology that can image the most critical small feature patterns for advanced integrated circuits. The semiconductor industry has adapted EUVL as the patterning technology of choice for printing critical features on 7 nm and smaller node devices in contact, via, metal line and cut layers, for example where the cuts can be applied to FinFET, nanosheet FET, or metal lines. Single exposure EUV enables chipmakers to pattern the most challenging features at 5 nm nodes. The significant improvement in EUV technology in the past few years allows for acceptable throughput using, e.g., ASML's EUV NXE:3400C scanner, which incorporates 0.33 numerical aperture (NA) lens. Extension of 0.33 NA EUV single exposure patterning to the 3 nm node and beyond requires continuous advancement in photoresist technology. Essential to the continuation of advanced patterning techniques is the development of lithographic patterning solutions to support High NA EUV. As the industry looks forward to the implementation of High NA (0.55 NA) EUV, the demand for new materials is heightened even further. These essential materials include photoresist, underlayer and rinse materials that will help the industry surpass the current requirements for Resolution, Line Width Roughness (LWR), and Sensitivity in modern photoresists while meeting the targets for stochastic and non-stochastic defectivity and etch pattern transfer. The requirement for balancing these properties is an industry wide challenge. It is essential to develop new chemistry and formulation strategies, as well as a fundamental understanding of these approaches in order to break this tradeoff and extend Moore's law into the future generations of devices.

### SUMMARY

An aspect provides a photoresist composition including a first polymer comprising a first repeating unit derived from a compound of Formula (1); a second polymer comprising a first repeating unit comprising an acid-labile group, a base-labile group, a base soluble group, or a combination thereof, wherein the first repeating unit of the second polymer is derived from a monomer comprising an ethylenically unsaturated polymerizable double bond; a photoacid generator; and a solvent, (1)

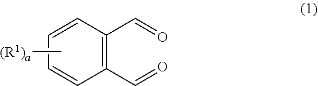

wherein, in Formula (1), each R¹ is a non-hydrogen substituent, each R¹ optionally further comprises one or more divalent linking groups as part of their structure, wherein each of the one or more divalent linking groups is independently substituted or unsubstituted, two adjacent R¹ optionally form a ring together, wherein the ring is substituted or unsubstituted, and a is an integer from 1 to 4.

Another aspect provides a pattern forming method that includes (a) applying a layer of the photoresist composition on a substrate; (b) soft-baking the composition layer; (c) exposing the soft-baked composition layer to activating radiation; (d) post-exposure baking the composition layer; and (e) developing the post-exposure baked composition layer using a developer to provide a resist relief image.

### BRIEF DESCRIPTION OF THE DRAWINGS

The following figures are exemplary embodiments.

FIGS. 1A and 1B shows the miscibility data for soft bake films using atomic force microscopy (AFM) according to one or more embodiments.

FIG. 2 is an image showing the aqueous developer wettability according to Example 17.

FIGS. 3A and 3B are images showing the aqueous developer wettability according to Examples 9 and 16, respectively.

FIG. 4 shows KrF contrast curves of Examples 7, 8, 9, 10, and 11.

FIG. 5 shows KrF contrast curves of Examples 9, 12, 14.

FIG. 6 shows KrF contrast curves of Examples 9, 16, and 17.

FIG. 7 shows KrF contrast curves of Examples 9, 13, and 15.

FIG. 8 shows scanning electron microscopy (SEM) images of Examples 7, 8, 9, 10, 11, 15, 16, and 17 after KrF exposure.

FIG. 9A shows a KrF contrast curve of Example 5.

FIG. 9B shows an EUV contrast curve of Example 5.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

A used herein, an “organic group” includes one or more carbon atoms, for example 1 to 60 carbon atoms. The term “hydrocarbon” refers to an organic compound or to an organic group having at least one carbon atom and at least one hydrogen atom. The term “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl-O—”; “carboxyl” and “carboxylic acid group” refer to a group having the formula “—C(═O)—OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl-O—”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic ring system that satisfies the Huckel Rule and includes carbon atoms in the ring, and optionally may include one or more heteroatoms selected from N, O, and S instead of a carbon atom in the ring; “aryl” refers to a monovalent aromatic monocyclic or polycyclic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl-O—”; and “arylthio” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl group” refers to an alkyl group having 1-4 or more heteroatoms instead of carbon; “heterocycloalkyl group” refers to a cycloalkyl group having 1-4 or more heteroatoms as ring members instead of carbon; “heterocycloalkylene group” refers to a heterocycloalkyl group having a valence of two; “heteroaryl group” refers to an aryl group having 1-4 or more heteroatoms as ring members instead of carbon; and “heteroarylene group” refers to an heteroaryl group having a valence of two.

Each of the foregoing substituent groups optionally may be substituted unless expressly provided otherwise. For example, where the group is cited without specifying that it is substituted or unsubstituted, the group includes both a group having no substituent and a group having a substituent. The term “optionally substituted” refers to being substituted or unsubstituted.

“Substituted” means that at least one hydrogen atom of the chemical structure is replaced with another terminal substituent group that is typically monovalent, provided that the designated atom's normal valence is not exceeded. When the substituent is oxo (i.e., ═O), then two geminal hydrogen atoms on the carbon atom are replaced with the terminal oxo group. Combinations of substituents or variables are permissible. Exemplary substituent groups that may be present on a “substituted” position include, but are not limited to, nitro (—NO₂), cyano (—CN), hydroxyl (—OH), oxo (═O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof; esters (including acrylates, methacrylates, and lactones) such as C₂₋₆ alkyl esters (—C(═O)O-alkyl or —OC(═O)-alkyl) and C₇₋₁₃ aryl esters (—C(═O)O-aryl or —OC(═O)-aryl), amido (—C(═O)NR′₂ wherein R′ is hydrogen or C₁₋₆ alkyl), carboxamido (—CH₂C(═O)NR′₂ wherein R′ is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—).

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present. For example, the term “haloalkyl” refers to an alkyl group substituted with one or more halogens. As used herein, “substituted C₁₋₈ haloalkyl” refers to a C₁₋₈ alkyl group substituted with at least one halogen, and is further substituted with one or more other substituent groups that are not halogens.

As used herein, an “acid-labile group” refers to a pendant group in which a bond is cleaved by the action of an acid, optionally and typically with thermal treatment, resulting in formation of a polar group, such as a carboxylic acid or alcohol group, being formed on the polymer, and optionally and typically with a moiety connected to the cleaved bond becoming disconnected from the polymer. As used herein, the term “acid-decomposable group” is synonymous with an acid-labile group. In other systems, a non-polymeric compound may include an acid-labile group that may be cleaved by the action of an acid, resulting in formation of a polar group, such as a carboxylic acid or alcohol group on a cleaved portion of the non-polymeric compound. Such acid is typically a photo-generated acid with bond cleavage occurring during post-exposure baking (PEB); however, embodiments are not limited thereto, and, for example, such acid may be thermally generated. Suitable acid-labile groups include, for example: tertiary alkyl ester groups, secondary or tertiary aryl ester groups, secondary or tertiary ester groups having a combination of alkyl and aryl groups, tertiary alkoxy groups, tertiary carbonate groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

As used herein, “acid-labile group” does not include groups that form a part of the polymer backbone. For example, it should be understood that the poly(phthalaldehyde) is not considered to be an acid-labile group, because the acid-labile functionality is present in the backbone of the polymer and not as a pendant group, such that acid cleavage produces monomer(s) or a polymer of reduced molecular weight. In such cases, the backbone of the poly(phthalaldehyde) may be cleaved to form aldehyde groups.

As used herein, when a definition is not otherwise provided, a “divalent linking group” refers to a divalent group including one or more of —O—, —S—, —Te—, —Se—, —C(O)—, —C(O)O—, —N(R^{a})—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R^{a} is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —C(O)O—, —N(R^{a})—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R^{a} is hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. More typically, the divalent linking group includes at least one of —O—, —C(O)—, —C(O)O—, —N(R^{a})—, —C(O)N(R^{a})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{a} is hydrogen, deuterium, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

In conventional CAR resists, the acid-labile group is typically pendant to the polymer backbone, such that the generated acid reacts with the acid-labile group to form a polymer with contrasting solubility but an identical degree of polymerization. However, if the acid-labile group is present in the polymer backbone, reaction with PAG induces a “chain-scission” mechanism, wherein solubility contrast is achieved by significantly reducing the degree of polymerization, and subsequently molecular weight, of the polymer. In some cases, such as poly(phthalaldehyde) resists, a secondary acid-catalyzed “unzipping” mechanism also occurs. With an unzipping mechanism, the acetal polymer backbone can react with an acid-catalyst to create an active chain-end group. Due to the thermodynamic properties of phthalaldehydes and their polymers, active chain-ends can induce complete depolymerization of the polymer into monomer at temperatures above the ceiling temperature (T_{c}). “Chain scission” and “unzipping”-type mechanisms have been developed as alternative and/or complimentary approaches to CAR as these mechanisms can overcome challenges with stochastics and the resolution-line width roughness-sensitivity trade off, which can limit resolution in current photoresists.

The present inventors have discovered photoresist formulations including poly(phthalaldehyde) (PPA)-type polymers with a new scope of phthalaldehyde (PA) monomer derivatives that provide improved polymer stability and increase the post-exposure bake process windows for PPA-containing photoresist compositions, in some cases by modifying the ceiling temperature of the resultant PPA material. In some cases, these substitutions may provide benefits such as improved solubility, better compatibility with PAGs and quenchers, stronger adhesion to substrates, or increased photo-sensitivity.

Provided herein is a photoresist composition that includes a first polymer, a second polymer, a photoacid generator, and a solvent. The first polymer includes a first repeating unit that is derived from a compound of Formula (1), as described herein. The second polymer includes a first repeating unit that includes an acid-labile group, a base-labile group, a base soluble group, or a combination thereof. The first repeating unit of the second polymer is derived from a monomer that includes an ethylenically unsaturated polymerizable double bond. As used herein, an ethylenically unsaturated double bond refers to substituted or unsubstituted C₂₋₂₀ alkenyl, preferably (meth)acrylate or C₂ alkenyl.

The first polymer includes a first repeating unit that is derived from a compound of Formula (1):

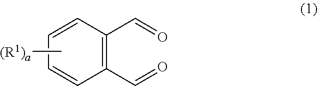

As will be appreciated by the person having ordinary skill in the art, the first polymer includes a first repeating unit derived from the compound of Formula (1), which has the following structure:

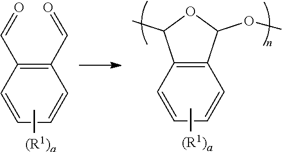

wherein R1 is as defined in Formula (1) and n is the number of repeating units.

In Formula (1), each R¹ is a non-hydrogen substituent. In some embodiments, each R¹ is a non-hydrogen substituent that does not include a silyl group. For example, in some embodiments, each R¹ independently may include fluorine, chlorine, bromine, iodine, nitrogen, oxygen, sulfur, or a combination thereof. In some embodiments, each R¹ may be independently selected from fluorine, chlorine, bromine, iodine, nitro, cyano, mono- or di-(C₁₋₁₀)alkylamino, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₁₋₃₀ alkoxy, substituted or unsubstituted C₃₋₃₀ cycloalkyl, substituted or unsubstituted C₃₋₃₀ heterocycloalkyl, substituted or unsubstituted C₅₋₃₀ cycloalkenyl, substituted or unsubstituted C₂₋₃₀ heterocycloalkenyl, substituted or unsubstituted C₆₋₃₀ aryl, or substituted or unsubstituted C₃₋₃₀ heteroaryl. Typically, each R¹ may be independently selected from fluorine, chlorine, bromine, iodine, nitro, or cyano.

In Formula (1), each R¹ optionally further comprises one or more divalent linking groups as part of their structure, wherein each of the one or more divalent linking groups is independently substituted or unsubstituted. Exemplary divalent linking groups include one or more of —O—, —S—, —Te—, —Se—, —C(O)—, —C(O)O—, —N(R^{a})—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R^{a} is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (1), two adjacent R¹ optionally form a ring together, wherein the ring is substituted or unsubstituted. For example, two adjacent groups R¹ may form a ring together that is cycloaliphatic, aromatic, heterocycloaliphatic, or heteroaromatic. When adjacent groups R¹ form a ring together, the resulting ring may be substituted or unsubstituted. Exemplary substituent groups include, but are not limited to, fluorine, chlorine, bromine, iodine, nitro, cyano, mono- or di-(C₁₋₁₀)alkylamino, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₁₋₃₀ alkoxy, substituted or unsubstituted C₃₋₃₀ cycloalkyl, substituted or unsubstituted C₃₋₃₀ heterocycloalkyl, substituted or unsubstituted C₅₋₃₀ cycloalkenyl, substituted or unsubstituted C₂₋₃₀ heterocycloalkenyl, substituted or unsubstituted C₆₋₃₀ aryl, substituted or unsubstituted C₃₋₃₀ heteroaryl, or a combination thereof. Each of these substituent groups may further include a divalent linking group as part of their structure, as detailed above for R¹.

In Formula (1), a is an integer from 1 to 4.

Non-limiting examples of the compound of Formula (1), include, but are not limited to, the following compounds:

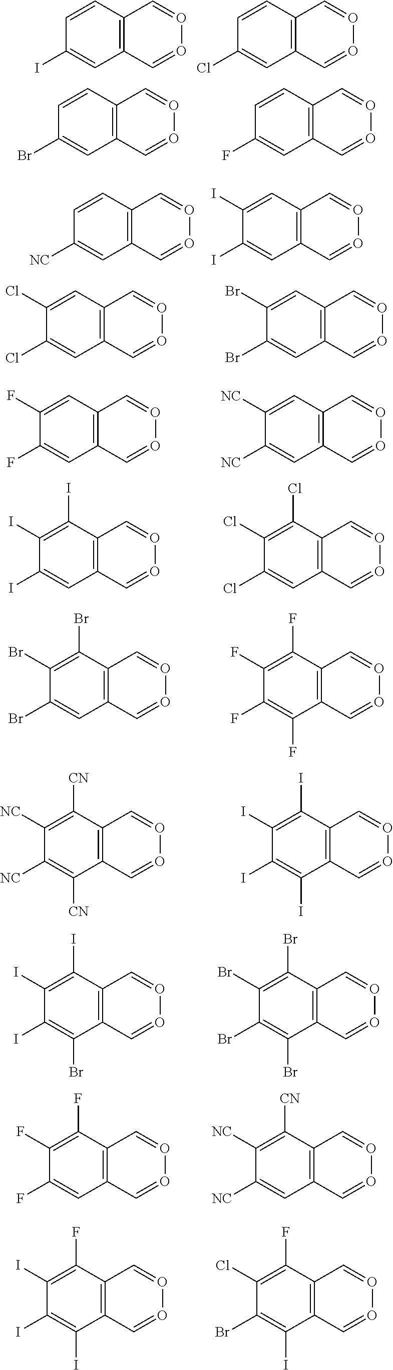

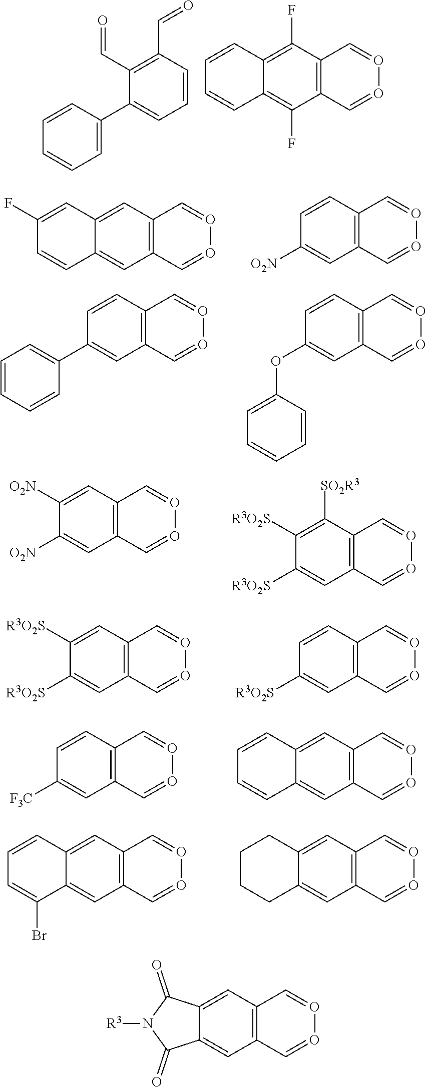

wherein R² and R³ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl; two adjacent R² optionally form a ring together, wherein the ring is substituted or unsubstituted, and two adjacent R³ optionally form a ring together, wherein the ring is substituted or unsubstituted.

The first polymer is derived from polymerization of a compound of Formula (1), such that the first polymer includes a first repeating unit that is derived from Formula (1). The first polymer may be a homopolymer or a copolymer. For example, the first polymer may include a first repeating unit that is derived from a first monomer of Formula (1), and a second repeating unit that is derived from a second monomer of Formula (1), wherein the first repeating unit and the second repeating unit in the first polymer are different from each other.

The person of ordinary skill in the art would understand that the disclosed first polymers are formed from reacting their corresponding monomers with an appropriate catalyst and/or initiator to induce a chain-growth polymerization. In certain embodiments, the first polymer is formed from a single monomer. In certain embodiments, the first polymer is a copolymer formed from at least two distinct monomers of Formula (1).

In some embodiments, the catalyst is a cationic catalyst or an anionic catalyst. In some embodiments, the catalyst is an anionic catalyst. In some embodiments, the anionic catalyst is selected from 1,8-diazobicyclo[5.4.0]undec-7-ene (DBU), triethylamine, or potassium tert-butoxide. Anionic catalysts may include metal alkoxides, amines, phosphazene bases, and organolithium reagents. In some embodiments, the catalyst is a cationic catalyst. In some embodiments, the cationic catalyst is selected from boron trifluoride diethyl etherate (BF₃OEt), and other Lewis acids such as tin (IV) chloride, gallium (III) chloride, titanium (IV) chloride, titanium (IV) fluoride, and/or iron (III) chloride. In some embodiments, the catalyst could be a combination of more than one species, or oligomeric, or polymeric species.

In preparing the first polymer, the anionic polymerization reaction of the compound of Formula (1) can proceed in the presence of a protic initiator additive. In some embodiments, the protic initiator additive is monofunctional. In some embodiments, the protic initiator additive is difunctional. In some embodiments, the protic initiator additive is polyfunctional, containing 3 or more protic initiating species on a single moiety. In some embodiments, the protic initiator additive may be selected from an alcohol, thiol, amine, oxime, carboxylate, or carbamate. In some embodiments, the protic initiator additive may be selected from ethylene glycol, diethylene glycol, triethylene glycol, ditrimethylolpropane, trimethylolpropane, pentaerythritol, or water.

In preparing the first polymer, the anionic polymerization reaction of the compound of Formula (1) can be quenched (i.e. the reaction is terminated) by the addition of an electrophilic quenching reagent. In some embodiments, the quenching reagent may be an acid chloride, an acid bromide, an acid anhydride, an isocyanate, a chloroformate, a bromoformate, an alkyl halide, or the like. In some embodiments, the quenching reagent may be selected from phenyl acetyl chloride, phenyl acetyl bromide, acetic anhydride, methacrylic anhydride, pivalic anhydride, ethyl chloroformate, or benzyl chloroformate. In some embodiments, the quenching reagent reacts with the first polymer to form an ester, carbonate, carbamate, or ether chain end.

In preparing the first polymer, the polymerization reaction of the compound of Formula (1) can proceed in an appropriate aprotic solvent. In some embodiments, the solvent is selected from the group consisting of dichloromethane, tetrahydrofuran, methyl tetrahydrofuran, toluene, pentane, chloroform, or combinations thereof.

The first polymer can be prepared by reacting the compound of Formula (1), and any additional monomers, for a suitable amount of time and at any suitable reaction temperatures. For example, the reaction temperature may be from 40° C. to −100° C., but embodiments are not limited thereto, and the reaction time may be from 1 minutes to 20 hours, preferably from 30 minutes to 8 hours. The monomer and/or initiators could be added prior to the polymerization, or added in several portions throughout, or control-fed into the polymerization pot.

The first polymer may be linear or cyclic. In some embodiments, the first polymer is linear.

The first polymer may have a molecular weight that is from about 1,000 Daltons to about 1,000,000 Daltons. The polydispersity index (PDI) of the first polymer, which is the ratio of M_{w} to number average molecular weight (Mₙ) is typically from 1.1 to 3, and more typically from 1.1 to 2. Molecular weight values are determined by gel permeation chromatography (GPC) using polystyrene standards.

The first polymer may be included in the photoresist composition in any suitable amount. In some embodiments, the first polymer may be included in the photoresist composition in an amount from 50 weight percent (wt %) to about 95 wt %, based on total solids. For example, the first polymer may be included in the photoresist composition in an amount from 55 wt % to 90 wt %, or from 60 wt % to 85 wt %, based on total solids, but embodiments are not limited thereto.

The photoresist composition also includes a second polymer that is different from the first polymer. The second polymer includes a first repeating unit that includes an acid-labile group, a base-labile group, a base soluble group, or a combination thereof, wherein the first repeating unit of the second polymer is derived from a monomer that includes an ethylenically unsaturated polymerizable double bond. In some embodiments, the second polymer is not a poly(arylene). For example, in some embodiments, the second polymer is not a novolac.

Suitable acid decomposable or labile groups include, for example, tertiary alkyl ester groups, secondary or tertiary aryl ester groups, secondary or tertiary ester groups having a combination of alkyl and aryl groups, tertiary alkoxy groups, acetal groups, ketal groups, tertiary carbonate groups, and tertiary carbamate groups. Typically, the acid labile group may be an acetal group, a ketal group, a tertiary carbonate group, a tertiary carbamate group, or a tertiary ester group. As used herein, the “tertiary carbamate group” includes tertiary carbamate ester groups having alkyl groups, tertiary carbamate ester groups having aryl groups, and tertiary carbamate ester groups having a combination of alkyl and aryl groups. As used herein, the “tertiary carbonate group” includes tertiary carbonate ester groups having alkyl groups, tertiary carbonate ester groups having aryl groups, and tertiary carbonate ester groups having a combination of alkyl and aryl groups. Preferably, the acid labile group includes a tertiary ester group.

Exemplary repeating units having an acid labile group include those represented by one or more of Formulae (2) to (6):

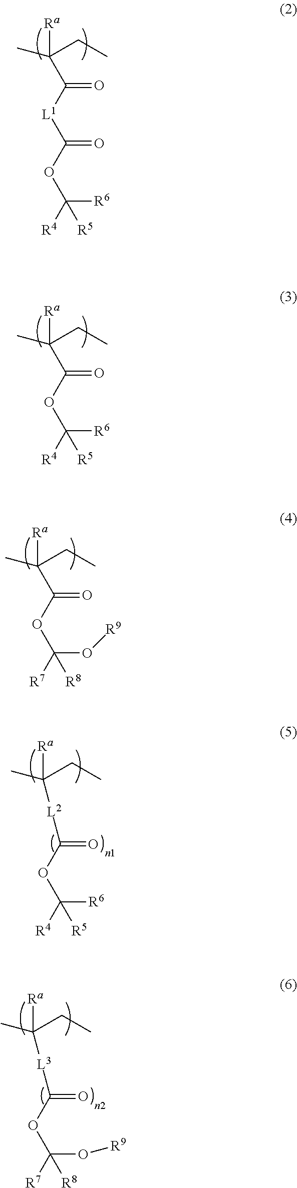

In Formulae (2) to (6), each R^{a} is independently hydrogen, deuterium, fluorine, cyano, substituted or unsubstituted C₁₋₁₀ alkyl, or substituted or unsubstituted C₁₋₁₀ fluoroalkyl. Preferably, R^{a} is hydrogen, fluorine, or substituted or unsubstituted C₁₋₅ alkyl, typically methyl.

In Formula (2), L¹ is a divalent linking group. For example, L¹ may be a divalent linking group including at least one carbon atom, at least one heteroatom, or a combination thereof. For example, L¹ may include 1 to 10 carbon atoms and at least one heteroatom. In one or more embodiments, L¹ may be —OCH₂—, —OCH₂CH₂O— or —N(R^{c})—, wherein R^{c} is hydrogen, deuterium, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

In Formulae (2), (3), and (5), R⁴ to R⁶ may each independently be hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl; provided that only one of R⁴ to R⁶ may be hydrogen, and provided that when one of R⁴ to R⁶ is hydrogen, one or both of the others of R⁴ to R⁶ are substituted or unsubstituted C₆₋₂₀ aryl or substituted or unsubstituted C₄₋₂₀ heteroaryl. Preferably, R⁴ to R⁶ are each independently substituted or unsubstituted C₁₋₆ alkyl or substituted or unsubstituted C₃₋₁₀ cycloalkyl.

In Formulae (2), (3), and (5), any two of R⁴ to R⁶ together optionally form a ring, and each of R⁴ to R⁶ optionally may include as part of their structure one or more groups chosen from —O—, —C(O)—, —N(R^{c})—, —S—, —S(O)—, or —S(O)₂—, wherein R^{c} may be hydrogen, deuterium, a straight chain or branched C₁₋₂₀ alkyl, monocyclic or polycyclic C₃₋₂₀ cycloalkyl, or monocyclic or polycyclic C₁₋₂₀ heterocycloalkyl. For example, any one or more of R⁴ to R⁶ may be independently a group of the formula —CH₂C(═O)CH₍₃₋ₙ₎Yₙ, where each Y is independently substituted or unsubstituted C₁₋₃₀ heterocycloalkyl, and n is 1 or 2. For example, each Y may be independently substituted or unsubstituted C₁₋₃₀ heterocycloalkyl including a group of the formula —O(C^{a1})(C^{a2})O—, wherein C^{a1} and C^{a2} are each independently hydrogen, deuterium or substituted or unsubstituted C₁₋₁₀ alkyl, and where C^{a1} and C^{a2} together optionally form a ring.

In Formulae (4) and (6), R⁷ and R⁸ may be each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₆₋₂₀ aryl, or substituted or unsubstituted C₂₋₂₀ heteroaryl; and R⁹ may be substituted or unsubstituted C₁₋₂₀ alkyl, substituted or unsubstituted C₃₋₂₀ cycloalkyl, or substituted or unsubstituted C₁₋₃₀ heterocycloalkyl. Preferably, R⁷ and R⁸ may be each independently hydrogen, deuterium, substituted or unsubstituted C₁₋₂₀ alkyl, substituted or unsubstituted C₃₋₂₀ cycloalkyl, or substituted or unsubstituted C₁₋₂₀ heterocycloalkyl.

Each of R⁷ to R⁹ optionally may include as part of their structure one or more groups chosen from —O—, —C(O)—, —N(R^{c})—, —S—, —S(O)—, or —S(O)₂—, wherein R^{c} may be hydrogen, deuterium, a straight chain or branched C₁₋₂₀ alkyl, monocyclic or polycyclic C₃₋₂₀ cycloalkyl, or monocyclic or polycyclic C₁₋₂₀ heterocycloalkyl.

Optionally, one of R⁷ or R⁸ together with R⁹ may form a heterocyclic ring. Optionally, R⁷ and R⁸ may form a ring together.

In Formulae (5) and (6), L² and L³ are each independently a single bond or a divalent linking group. Preferably, L² and L³ are each independently substituted or unsubstituted C₆₋₃₀ arylene or substituted or unsubstituted C₃₋₃₀ cycloalkylene. For example, in some embodiments, L³ does not include a (meth)acrylate group as part of its structure.

In Formulae (5) and (6), each of n1 and n2 may independently be 0 or 1. It is to be understood that when n1 or n2 is 0, the corresponding L² or L³ group is connected directly to the respective oxygen atom.

Non-limiting examples of repeating units having an acid labile group include the following:

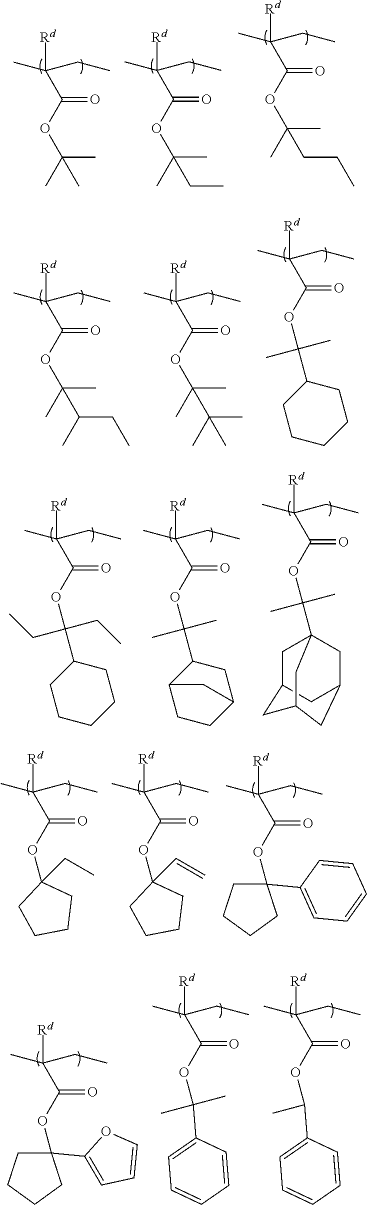

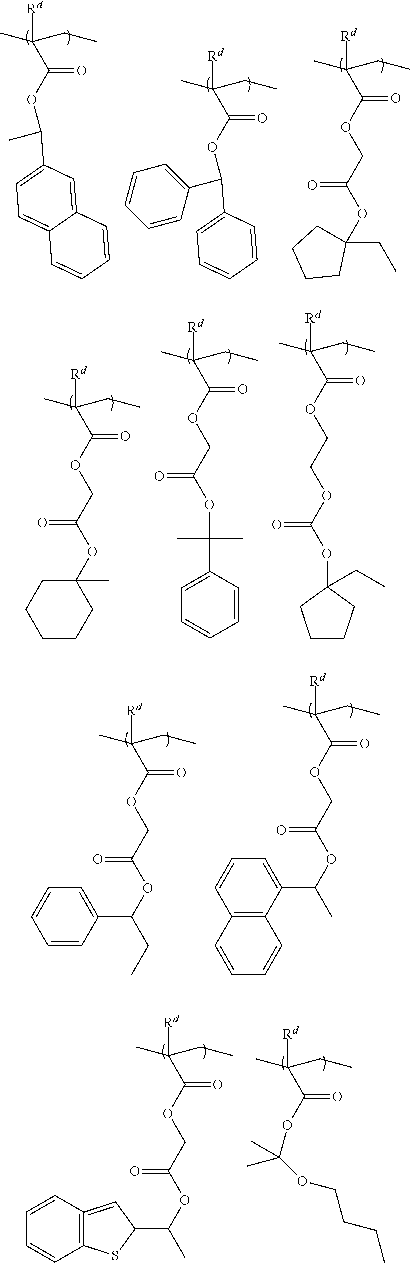

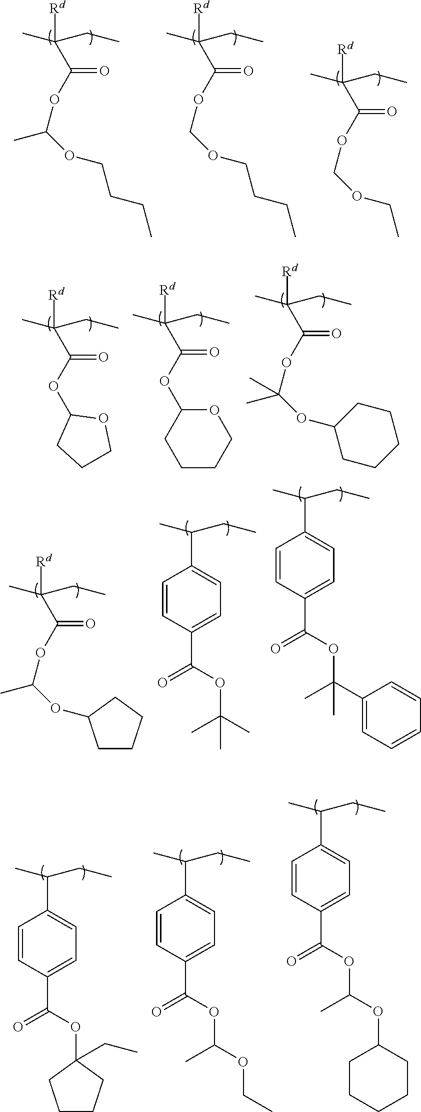

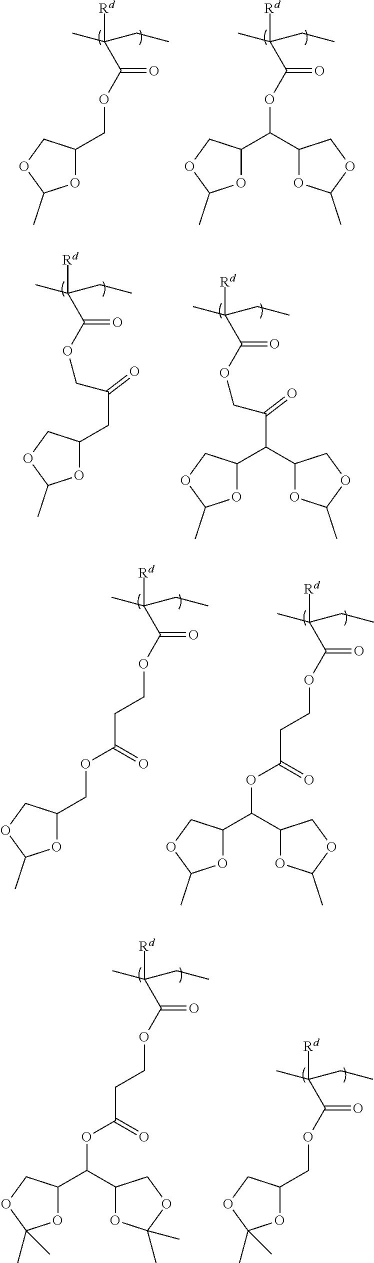

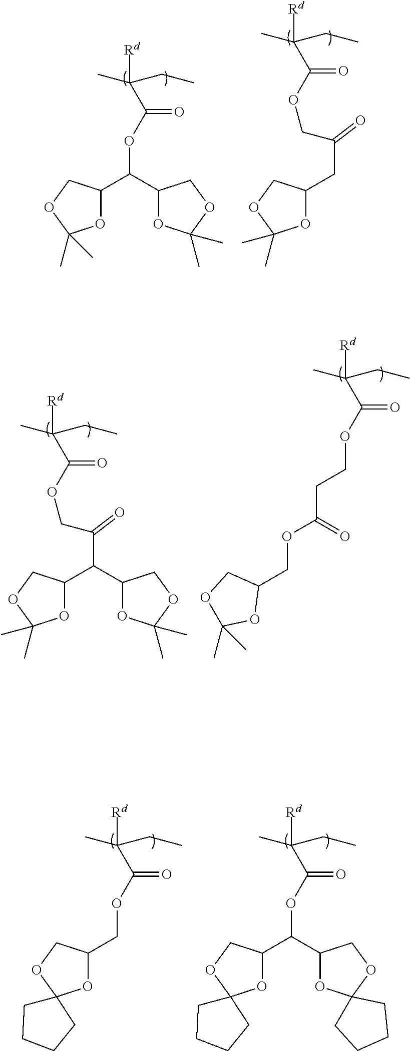

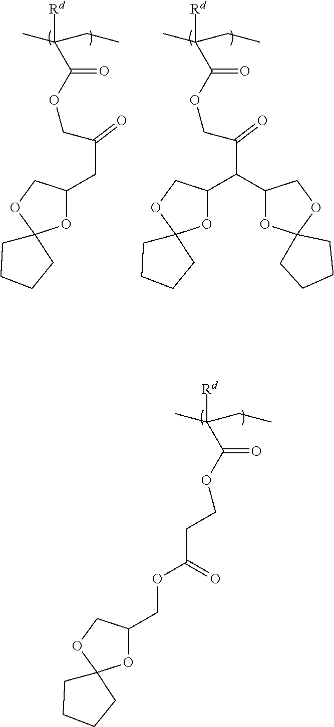

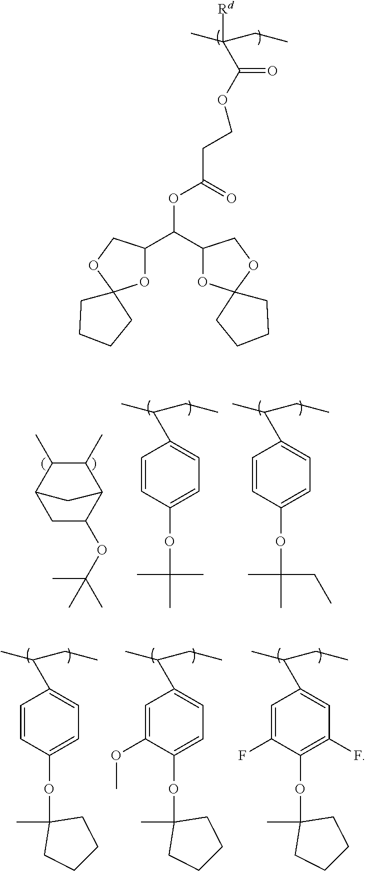

wherein R^{d} is hydrogen, deuterium, halogen, substituted or unsubstituted C₁₋₆ alkyl, or substituted or unsubstituted C₃₋₆ cycloalkyl.

The repeating unit having an acid-labile group may be present in the second polymer in an amount from 5 to 85 mol %, more typically from 15 to 50 mol %, still more typically from 30 to 50 mol %, based on total repeating units in the second polymer.

The second polymer may include a repeating unit, for example a first repeating unit, that includes a base-labile group. As referred to herein, base-labile groups are functional groups that can undergo cleavage reaction to provide polar groups such as hydroxyl, carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the photoresist composition that comprises the base-labile group. Thus, for instance, a base-labile group will be substantially inert during pre-exposure soft-bake, exposure, and post-exposure bake steps. By “substantially inert” it is meant that 55%, typically 1%, of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26 N aqueous solution of TMAH may be used for single puddle development or dynamic development, e.g., where the 0.26 N TMAH developer is dispensed onto an imaged photoresist layer for a suitable time such as 10 to 120 seconds (s). An exemplary base-labile group is an ester group, typically a fluorinated ester group. In some cases, the second polymer including the base-labile group is substantially not miscible with and has a lower surface energy than the first polymer and other solid components of the composition. When coated on a substrate, the polymer including the base-labile group can thereby segregate from other solid components of the composition to a top surface of the formed photoresist layer.

The base-labile repeating unit may be derived from one or more monomers of formula (7):

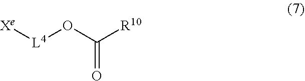

In Formula (7), X^{e} is a polymerizable group, typically selected from substituted or unsubstituted C₂₋₂₀ alkenyl or substituted or unsubstituted (meth)acryloyl.

In Formula (7), L⁴ is a divalent linking group that may include, for example, one or more of substituted or unsubstituted C₁₋₂₀ alkylene, substituted or unsubstituted C₃₋₂₀ cycloalkylene, —C(O)—, or —C(O)O—.

In Formula (7), R¹⁰ is substituted or unsubstituted C₁₋₂₀ fluoroalkyl, provided that the carbon atom bonded to the carbonyl (C═O) in Formula (7) is substituted with at least one fluorine atom.

Exemplary repeating units derived from monomers of formula (7) may include the following:

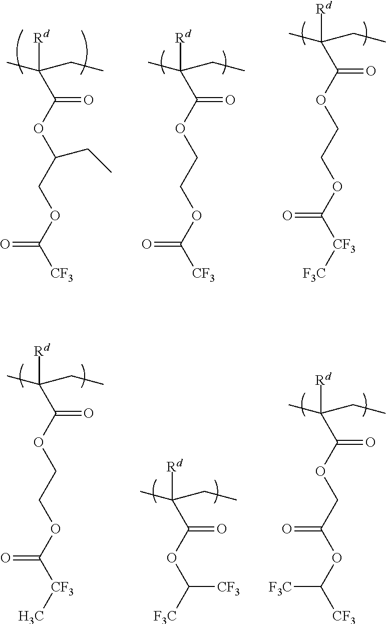

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The second polymer may include a repeating unit including two or more base-labile groups. For example, the second polymer can include a repeating unit derived from one or more monomers of formula (8):

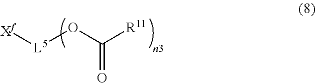

In Formula (8), X^{f} is a polymerizable group as defined for X^{e}.

In Formula (8), R¹¹ is substituted or unsubstituted C₁₋₂₀ fluoroalkyl, provided that the carbon atom bonded to the carbonyl (C═O) in Formula (8) is substituted with at least one fluorine atom.

In Formula (8), L⁵ is a polyvalent linking group including one or more of substituted or unsubstituted C₁₋₂₀ alkylene, substituted or unsubstituted C₃₋₂₀ cycloalkylene, —C(O)—, or —C(O)O—.

In Formula (8), n3 is an integer of 2 or greater, for example 2 or 3.

Exemplary repeating units derived from monomers of Formula (8) may include the following:

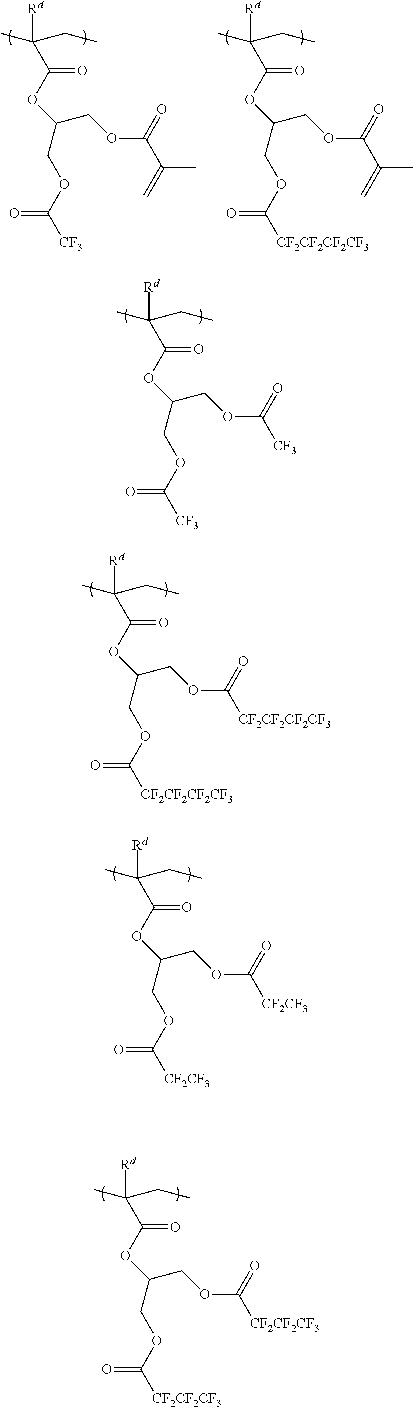

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

For example, the second polymer can include a repeating unit derived from one or more monomers of Formula (9):

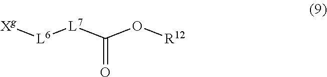

In Formula (9), X^{g} is a polymerizable group as defined for X^{e}.

In Formula (9), R¹² is substituted or unsubstituted C₁₋₂₀ alkyl.

In Formula (9), L⁶ is a divalent linking group.

In Formula (9), L⁷ is substituted or unsubstituted C₁₋₂₀ fluoroalkylene wherein the carbon atom bonded to the carbonyl (C═O) in Formula (9) is substituted with at least one fluorine atom.

Exemplary repeating units derived from monomers of Formula (9) may include the following:

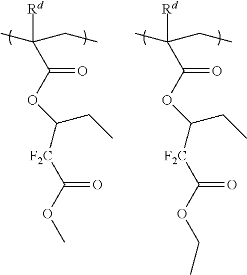

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit having a base-labile group is present in the second polymer in an amount from 10 to 95 mol %, more typically from 15 to 80 mol %, still more typically from 30 to 50 mol %, based on total repeating units in the second polymer.

The second polymer may include one or more repeating units having a base-soluble group. As referred to herein, base soluble groups are generally polar functional groups that could be ionized in the TMAH type of base and is thus soluble during the development stage.

For example, the repeating unit including a base-soluble group may include one or more of Formulae (10), (11), or (12):

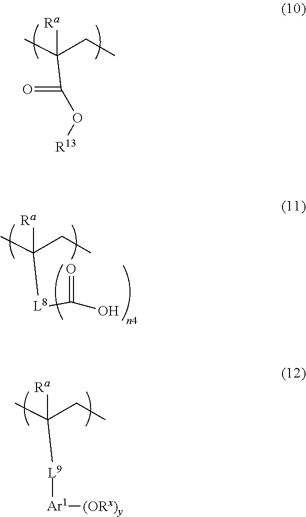

In Formulae (10), (11), or (12), R^{a} may each independently be hydrogen, fluorine, cyano, or substituted or unsubstituted C₁₋₁₀ alkyl. Preferably, R^{a} may each independently be hydrogen, fluorine, or substituted or unsubstituted C₁₋₅ alkyl, typically methyl.

In Formula (10), R¹³ may be substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or substituted or unsubstituted poly(C₁₋₃ alkylene oxide). Preferably, the substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of halogen, a fluoroalkyl group such as a C₁₋₄ fluoroalkyl group, typically fluoromethyl, a sulfonamide group —NH—S(O)₂—Y¹ where Y¹ is F or C₁₋₄ perfluoroalkyl (e.g., —NHSO₂CF₃), or a fluoroalcohol group (e.g., —C(CF₃)₂OH).

In Formula (11), L^{B} represents a single bond or a multivalent linking group chosen, for example, from optionally substituted aliphatic, such as C₁₋₆ alkylene or C₃₋₂₀ cycloalkylene, and aromatic hydrocarbons, and combinations thereof, optionally with one or more linking moieties chosen from —O—, —C(O)—, —C(O)O—, —S—, —S(O)₂—, —NR¹⁰²—, or —C(O)N(R¹⁰²)—, wherein R¹⁰² is chosen from hydrogen and optionally substituted C₁₋₁₀ alkyl. For example, the polymer may further include a repeating unit derived from one or more monomers of Formula (11) wherein L⁸ is a single bond, or a multivalent linking group selected from substituted or unsubstituted C₁₋₂₀ alkylene, substituted or unsubstituted C₃₋₂₀ cycloalkylene, and substituted or unsubstituted C₆₋₂₄ arylene, typically substituted or unsubstituted C₁₋₆ alkylene, substituted or unsubstituted C₃₋₁₀ cycloalkylene, or substituted or unsubstituted C₆₋₂₄ arylene.

In Formula (11), n4 is an integer from 1 to 5, typically 1. It is to be understood that when n4 is 1, the group L⁸ is a divalent linking group. It is to be understood that when n4 is 2, the group L⁸ is a trivalent linking group. Similarly, it is to be understood that when n4 is 3, the group L⁸ is a tetravalent linking group; when n4 is 4, the group L⁸ is a pentavalent linking group; and when n4 is 5, the group L⁸ is a hexavalent linking group. Accordingly, in the context of Formula (11), the term “multivalent linking group” refers to any of a divalent, trivalent, tetravalent, pentavalent, and/or hexavalent linking groups. In some aspects, when n4 is 2 or greater, the carboxylic acid groups (—C(O)OH) may be connected to the same atom of the linking group L⁸. In other aspects, when n4 is 2 or greater, the carboxylic acid groups (—C(O)OH) may be connected to different atoms of the linking group L⁸.

In Formula (12), L⁹ represents a single bond or a divalent linking group. Preferably, L⁹ may be a single bond, substituted or unsubstituted C₆₋₃₀ arylene, or substituted or unsubstituted C₆₋₃₀ cycloalkylene.

In Formula (12), Ar¹ is a substituted C₅₋₆₀ aromatic group that optionally includes one or more aromatic ring heteroatoms chosen from N, O, S, or a combination thereof, wherein the aromatic group may be monocyclic, non-fused polycyclic, or fused polycyclic. When the C₅₋₆₀ aromatic group is polycyclic, the ring or ring groups may be fused (such as naphthyl or the like), non-fused, or a combination thereof. When the polycyclic C₅₋₆₀ aromatic group is non-fused, the ring or ring groups may be directly linked (such as biaryls, biphenyl, or the like) or may be bridged by a heteroatom (such as triphenylamino or diphenylene ether). In some aspects, the polycyclic C₅₋₆₀ aromatic group may include a combination of fused rings and directly linked rings (such as binaphthyl or the like).

In Formula (12), y may be an integer from 1 to 12, preferably from 1 to 6, and typically from 1 to 3. Each R^{x} may independently be hydrogen or methyl.

Non-limiting examples of repeating units of Formulae (10), (11), or (12) include one or more of the following:

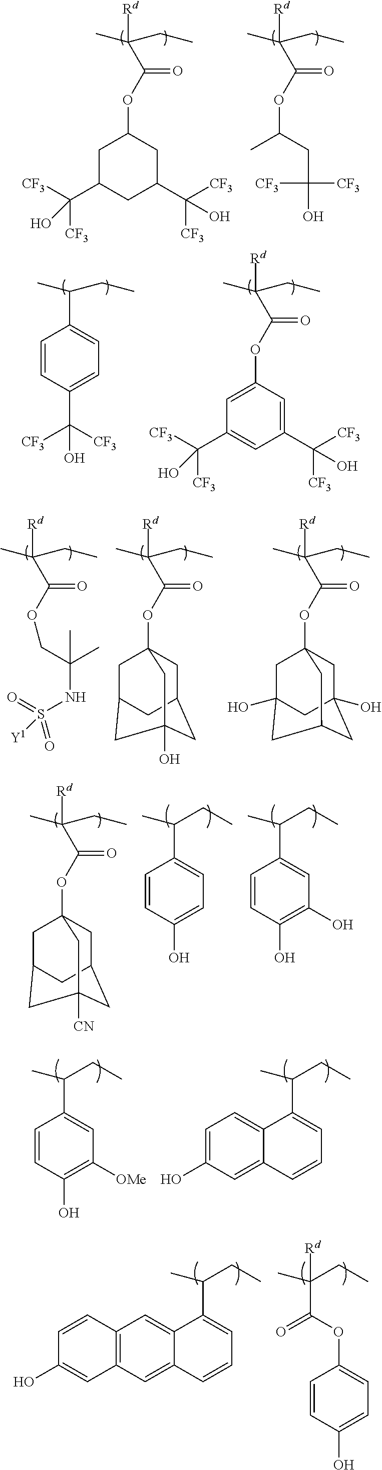

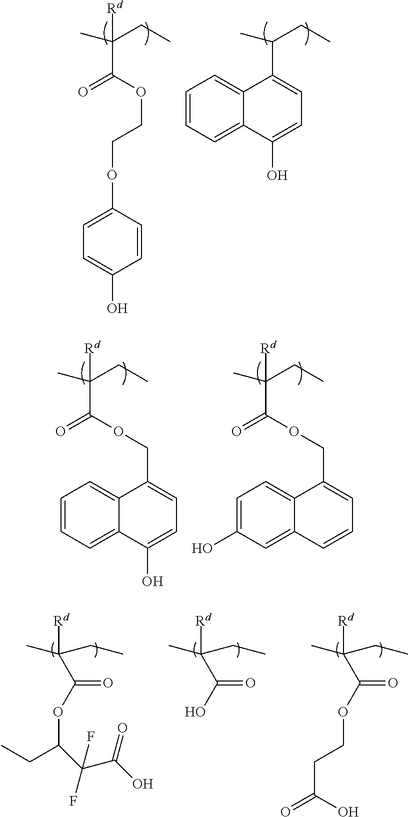

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit having a base-soluble group may be present in the second polymer in an amount from 10 to 85 mol %, more typically from 15 to 50 mol %, still more typically from 30 to 50 mol %, based on total repeating units in the second polymer.

The second polymer may further include one or more additional repeating units besides the first repeating unit comprising an acid-labile group, a base-labile group, a base soluble group, or a combination thereof. The additional repeating units may be, for example, one or more units for purposes of adjusting properties of the composition, such as etch rate and solubility. Exemplary repeating units may include those derived from one or more of (meth)acrylate, vinyl aromatic, vinyl ether, vinyl ketone, and/or vinyl ester monomers. The second polymer of the composition may be a homopolymer or a copolymer that includes two or more structurally different repeating units. For example, the second polymer may include one or more repeating units that include a functional group selected from a lactone-containing group, a sultone-containing group, a crosslinkable group, a crosslinking group, or the like, or a combination thereof.

A repeating unit of the second polymer may include a salt group. As used herein, a “salt group” refers to a moiety having a positive charge and/or a negative charge, such as having a positively charged or negatively charged moiety that is bonded pendant to the backbone of the second polymer. The repeating unit of the second polymer including a salt group may comprise a photoacid generator (PAG) group or a photo-decomposable quencher (PDQ) group. For example, a repeating unit of the second polymer may include a salt group that is represented by Formula (14a) or (14b):

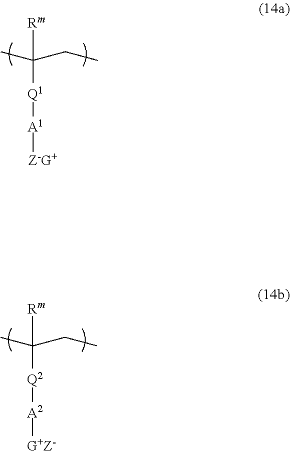

In Formulae (14a) and (14b), each R^{m} may be hydrogen, deuterium, fluorine, cyano, or substituted or unsubstituted C₁₋₁₀ alkyl. Preferably, R^{m} is hydrogen, fluorine, or substituted or unsubstituted C₁₋₅ alkyl, typically methyl.

In Formulae (14a) and (14b), Q¹ and Q² may each be independently a single bond or a divalent linking group. Preferably, Q¹ and Q² may each independently include 1 to 10 carbon atoms and at least one heteroatom, more preferably —C(O)—O—.

In Formulae (14a) and (14b), A¹ and A² may be each independently one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, or substituted or unsubstituted C₃₋₃₀ heteroarylene. In some embodiments, A¹ and A² may be each independently a divalent C₁-30 perfluoroalkylene group that is optionally substituted.

In Formula (14a), Z⁻ is an anionic moiety that is bonded to A¹, the conjugated acid of which typically has a pKa from −15 to 10. Z⁻ may be a sulfonate, a carboxylate, an anion of a sulfonamide, an anion of a sulfonimide, or a methide anion.

In Formula (14a), G⁺ is an organic cation as defined herein. In some embodiments, G⁺ is an iodonium cation substituted with two alkyl groups, two aryl groups, or a combination of alkyl and aryl groups; or a sulfonium cation substituted with three alkyl groups, three aryl groups, or a combination of alkyl and aryl groups.

In Formula (14b), Z⁻ is an anion compound as defined herein, the conjugated acid of which typically has a pKa from −15 to 10. Z⁻ may be a sulfonate, a carboxylate, an anion of a sulfonamide, an anion of a sulfonimide, or a methide anion species.

In Formula (14b), G⁺ is an organic cation that is bonded to A². For example, G⁺ may include an iodonium cation substituted with two alkyl groups, two aryl groups, or a combination of alkyl and aryl groups; or a sulfonium cation substituted with three alkyl groups, three aryl groups, or a combination of alkyl and aryl groups.

In still other embodiments, when the second polymer includes a repeating unit having a salt group, the second polymer may include a zwitterionic species. For example, the second polymer may include repeating units having a salt group of the Formula (14c):

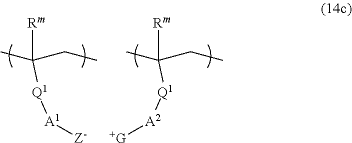

wherein, in Formula (14c), each R^{m} is independently as defined for Formulae (14a) and (14b).

In Formula (14c), Q¹, A¹, and Z⁻ are as defined in Formula (14a), and Q², A², and G⁺ are as defined in Formula (14b).

Exemplary repeating units of Formula (14a) include the following:

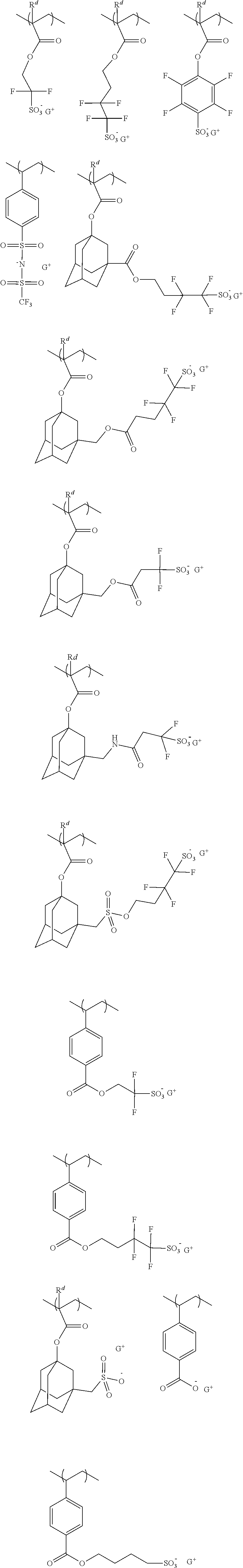

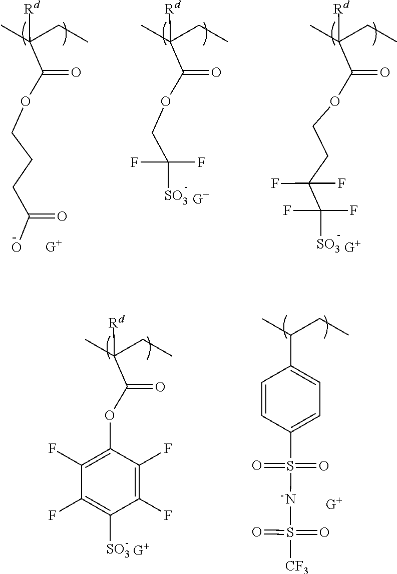

wherein G⁺ is the organic cation, and each R^{d} is independently as defined for R^{m} in Formulae (14a).

Exemplary repeating units of Formula (14b) include the following:

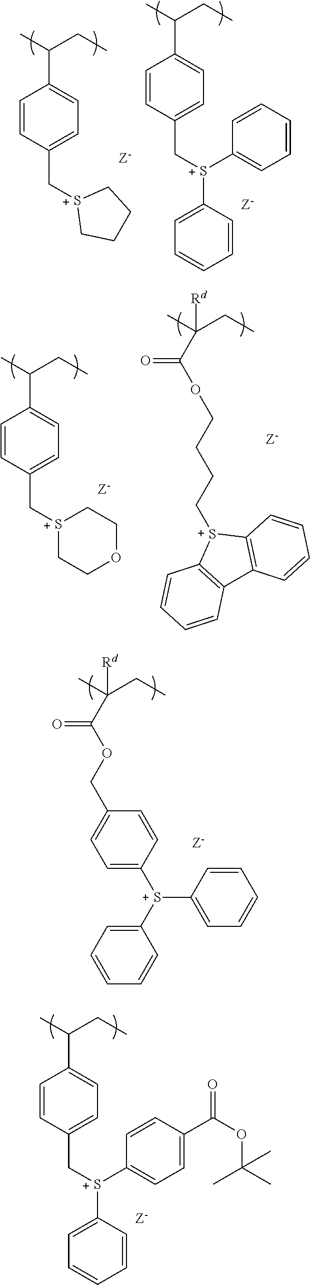

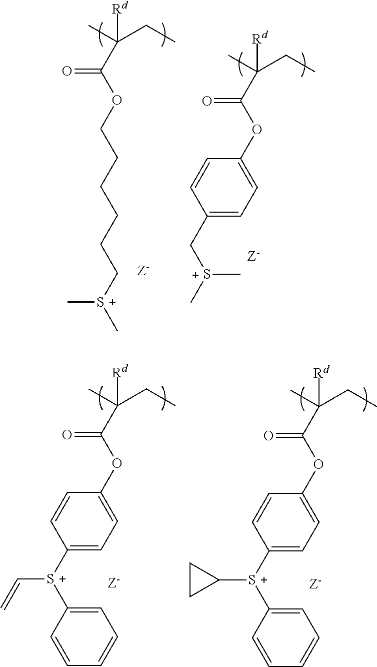

wherein Z⁻ is an anion group as defined herein, and each R^{d} is independently as defined for R^{m} in Formulae (14b).

The repeating unit of the second polymer including a salt typically may be present in an amount from 1 to 35 mol %, typically from 1 to 25 mol %, more typically from 2 to 15 mol %, based on total repeating units of the second polymer.

Non-limiting exemplary second polymers of the present invention include one or more of the following:

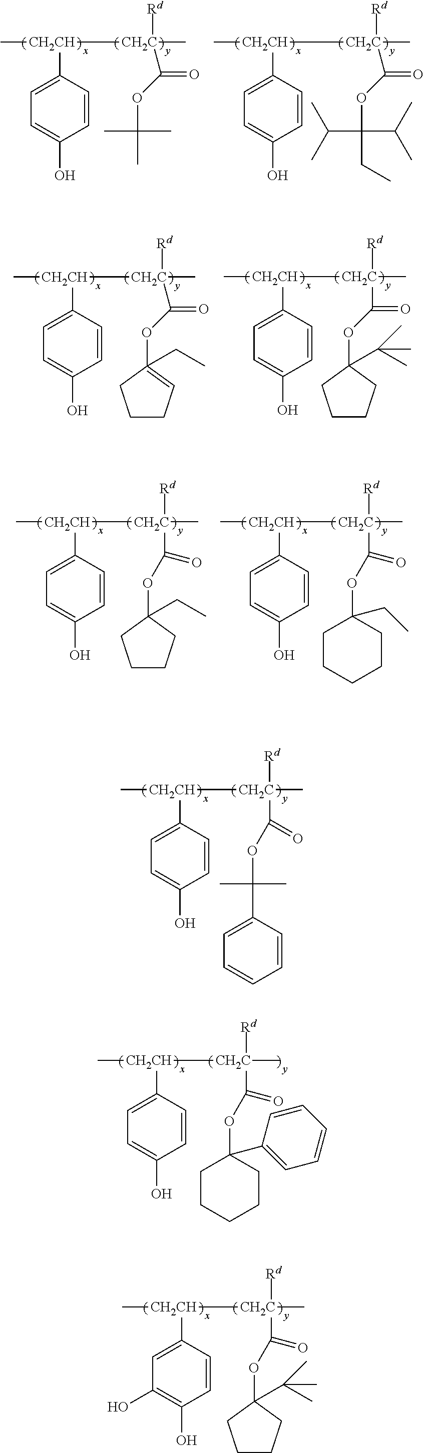

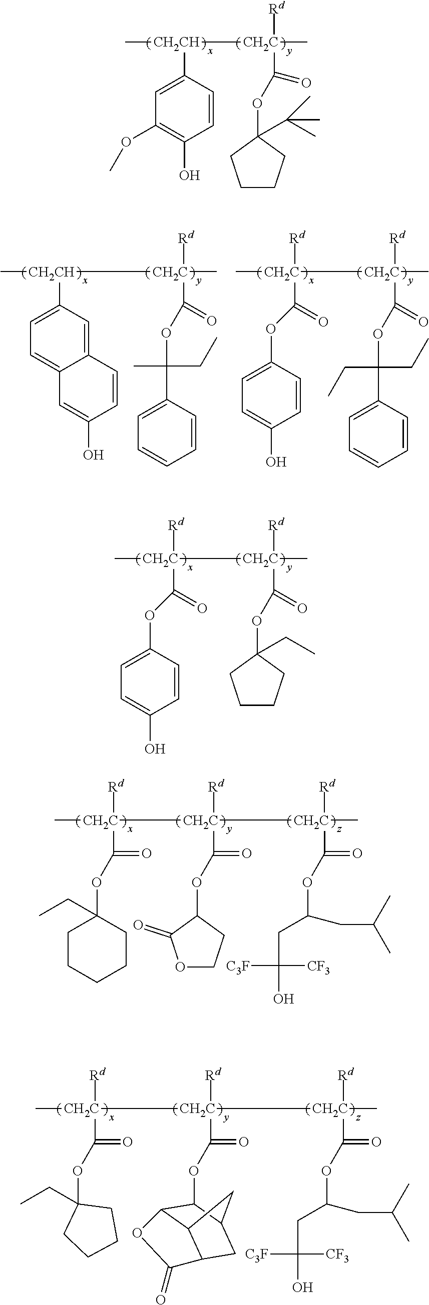

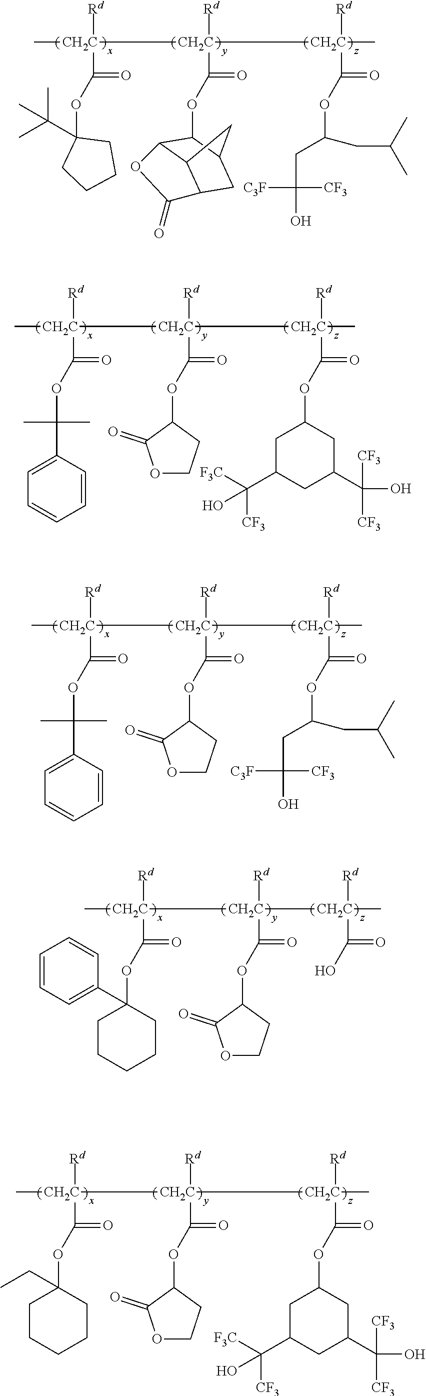

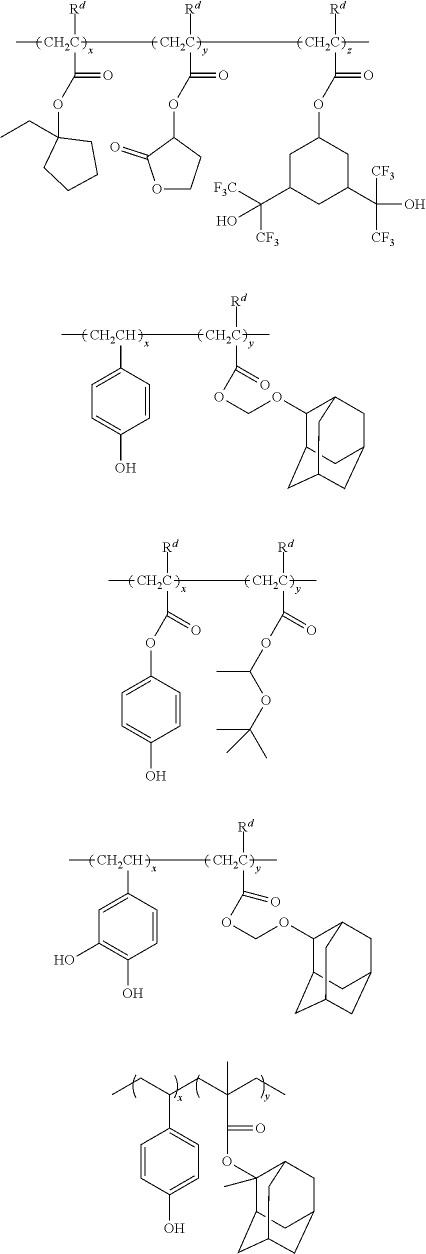

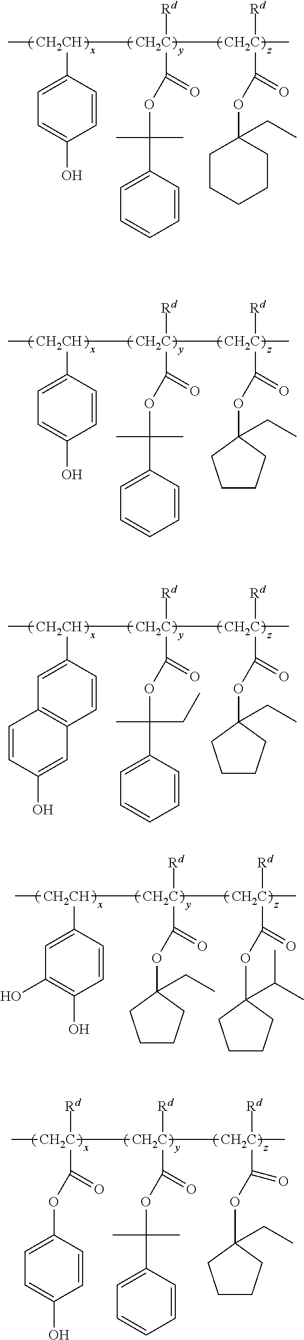

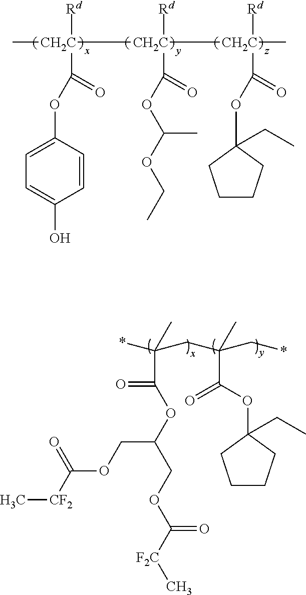

wherein each of x, y and z is a molar fraction of an associated repeating unit, wherein the sum of the molar fractions for each polymer adds up to 1, and wherein each R^{d} independently may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The second polymer typically has a weight average molecular weight (M_{w}) from 1,000 to 50,000 Dalton (Da), preferably from 2,000 to 30,000 Da, more preferably 3,000 to 20,000 Da, and still more preferably from 4,000 to 15,000 Da. The polydispersity index (PDI) of the second polymer, which is the ratio of M_{w} to number average molecular weight (Mₙ) is typically from 1.1 to 3, and more typically from 1.1 to 2. Molecular weight values are determined by gel permeation chromatography (GPC) using polystyrene standards.

In the compositions of the invention, the second polymer is typically present in the photoresist composition in an amount from 2 to 84 wt %, typically from 2 to 49 wt %, and more typically from 2 to 10 wt %, based on total solids of the photoresist composition. It will be understood that total solids includes the first and second polymers, PAGs, and other non-solvent components.

The second polymer may be prepared using any suitable method(s) in the art. For example, one or more monomers corresponding to the repeating units described herein may be combined, or fed separately, using suitable solvent(s) and initiator, and polymerized in a reactor. For example, the second polymer may be obtained by polymerization of the respective monomers under any suitable conditions, such as by heating at an effective temperature, irradiation with actinic radiation at an effective wavelength, or a combination thereof.

The photoresist composition also includes a photoacid generator (PAG). The PAG may be in ionic or non-ionic form. The PAG may be in a polymeric or non-polymeric form. In polymeric form, the PAG may be present as a moiety in a repeating unit of a polymer that is derived from a polymerizable PAG monomer. In some embodiments, the PAG is not included in the structure of the first polymer.

In some embodiments, the photoresist composition may include two or more different photoacid generator compounds.

Suitable PAG compounds maybe of the formula G⁺Z⁻, wherein G⁺ is an electroactive cation and Z⁻ is an anion that can generate a photoacid. The electroactive cation is preferably chosen from onium cations, preferably iodonium or sulfonium cations. Particularly suitable anions include those whose conjugated acids have a pKa of from −15 to 10. The anion is typically an organic anion having a sulfonate group or a non-sulfonate-type group, such as sulfonamidate, sulfonimidate, methide, or borate.

In some aspects, the anion of the PAG does not include and is free of —F, —CF₃, or —CF₂— groups. It should be understood that “free of —F, —CF₃, or —CF₂— groups” means that the anion of the PAG excludes groups such as —CH₂CF₃ and —CH₂CF₂CH₃. In still other aspects, the anion of the PAG is free of fluorine (i.e., does not contain a fluorine atom and is not substituted by a fluorine-containing group). In some aspects, the photoacid generator is free of fluorine (i.e., both the photoactive cation and the anion are free of fluorine).

The ionic PAG compound includes an organic cation, also referred to herein as G⁺. For example, the organic cation may be a sulfonium cation or an iodonium cation. In some embodiments, the organic cations may be a sulfonium cation of Formula (15) or an iodonium cation of Formula (16):

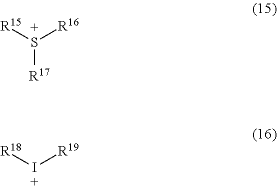

In Formulae (15) and (16), R¹⁵ to R¹⁹ are each independently substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, or substituted or unsubstituted C₄₋₂₀ heteroarylalkyl, or combinations thereof. Each of R¹⁵ to R¹⁷ may be either separate or connected to another group of R¹⁵ to R¹⁷ via a single bond or a divalent linking group to form a ring. R¹⁸ and R¹⁹ may be either separate or connected to each other via a single bond or a divalent linking group to form a ring. Each of R¹⁵ to R¹⁹ optionally may include as part of its structure a divalent linking group. Each of R¹⁵ to R¹⁹ independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups.

Exemplary sulfonium cations of Formula (15) include one or more of the following:

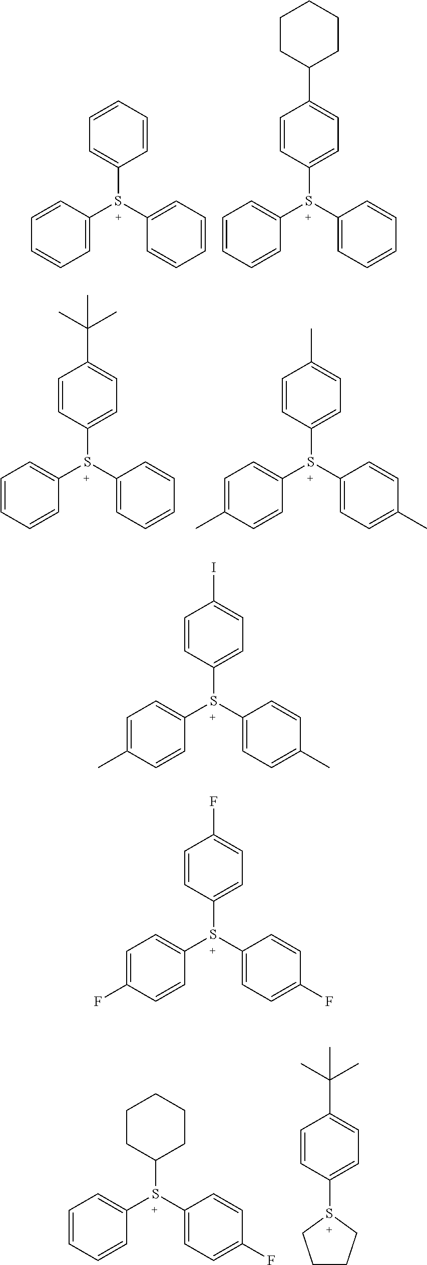

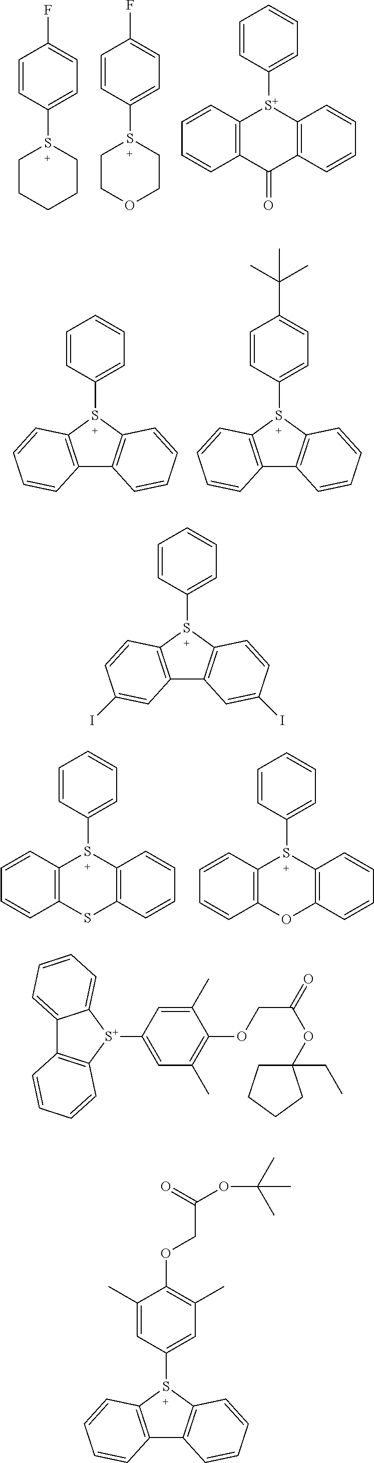

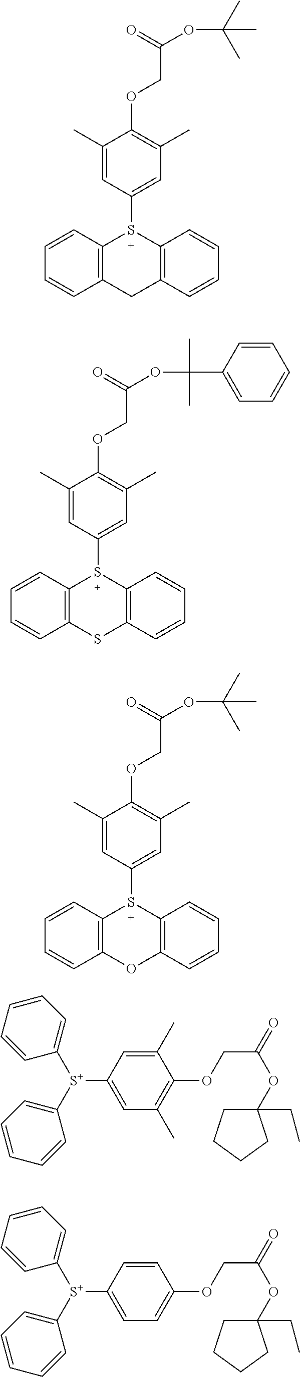

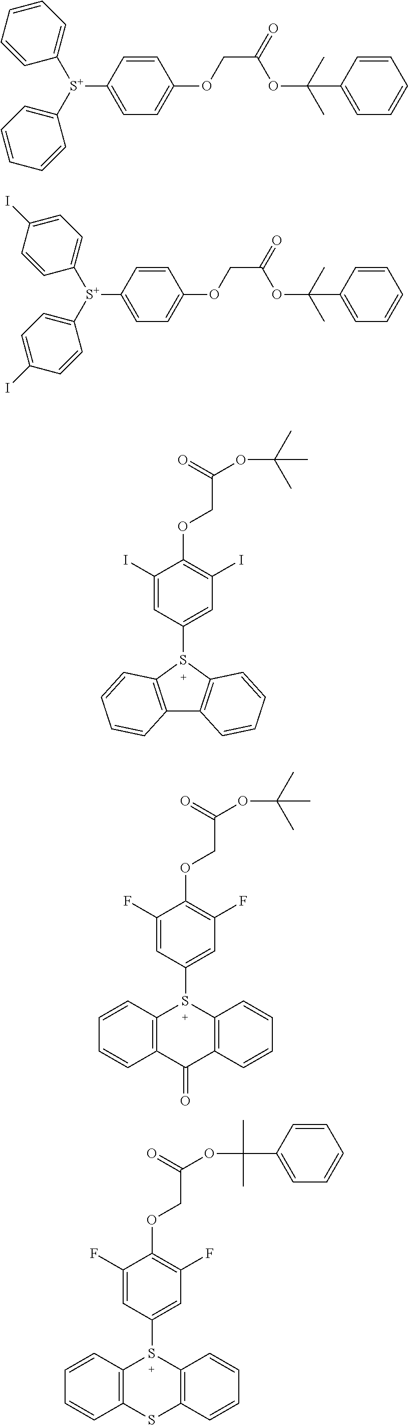

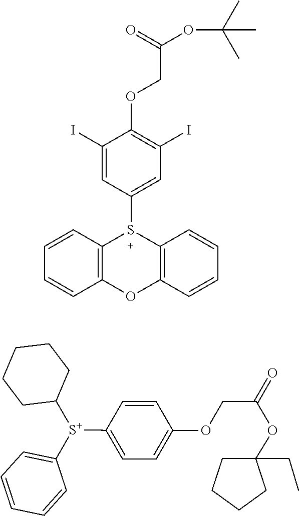

Exemplary iodonium cations of Formula (16) may include one or more of the following:

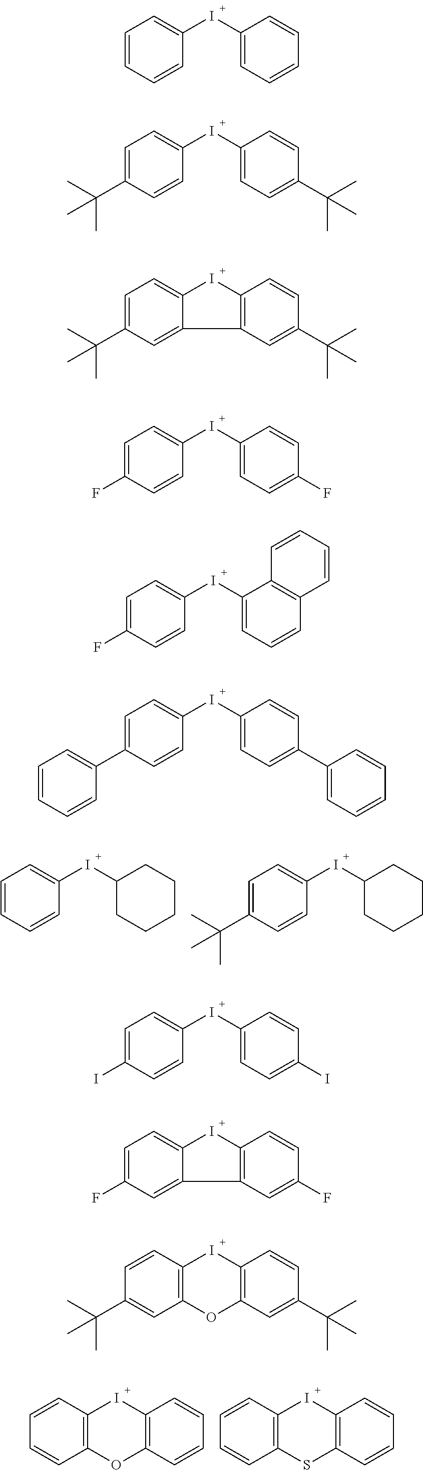

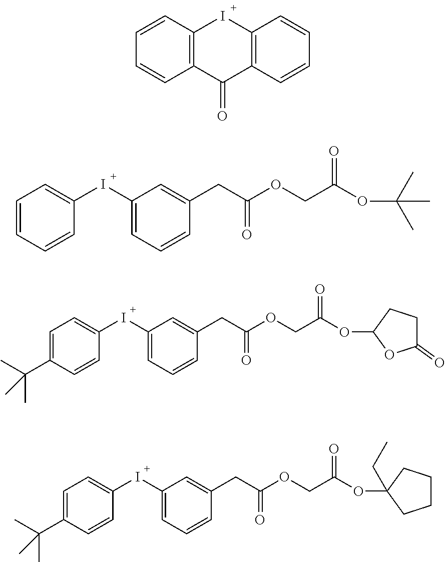

Exemplary organic anions, also referred to herein as Z⁻, having a sulfonate group include one or more of the following:

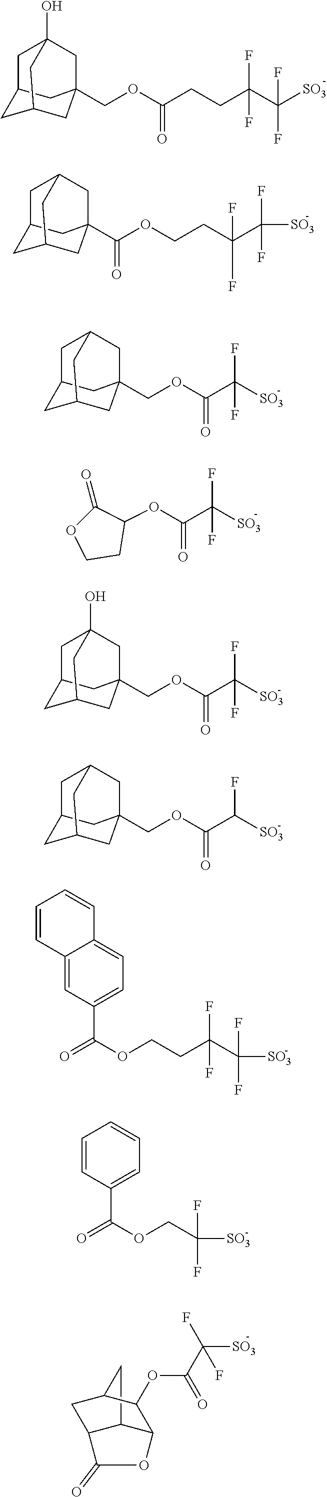

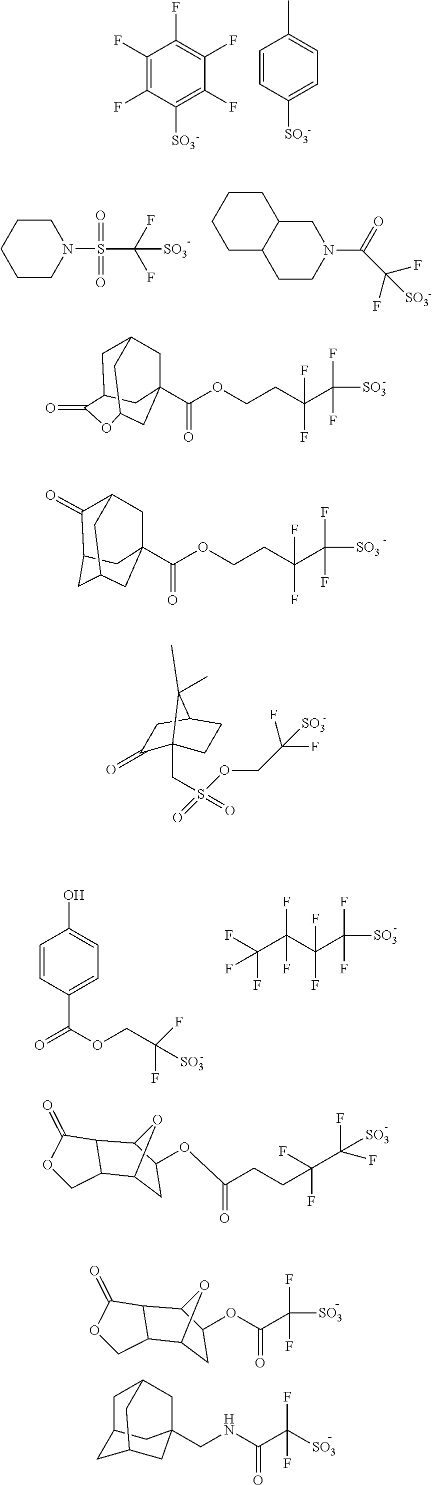

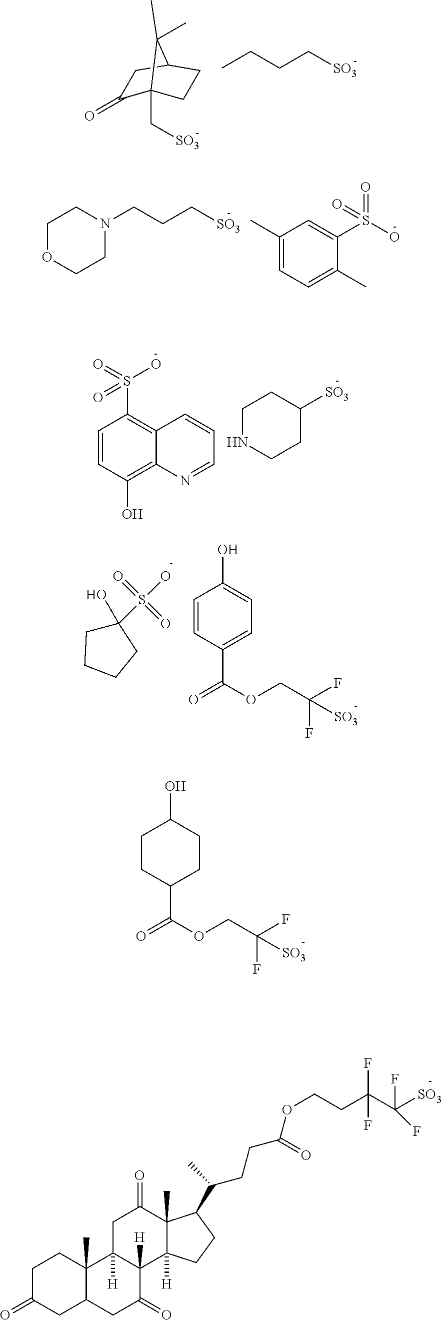

Exemplary non-sulfonated anions, also referred to herein as Z⁻, include one or more of the following:

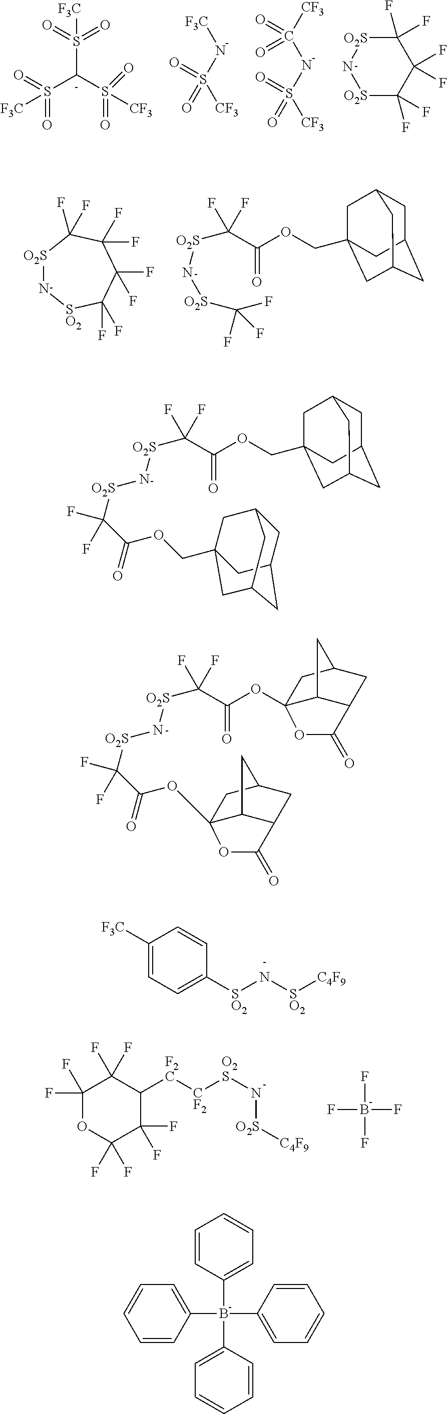

Commonly used onium salts may include, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Other useful PAG compounds are known in the art of chemically amplified photoresists and include, for example: non-ionic sulfonyl compounds, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable photoacid generators are further described in U.S. Pat. Nos. 8,431,325 and 4,189,323.

In some embodiments, the PAG compound may be a non-ionic PAG compound. In some embodiments, the non-ionic PAG may include a sulfonyl-ester, an imino-ester, an imido-ester, or the like, or a combination thereof.

Exemplary non-ionic PAGs include one or more of the following:

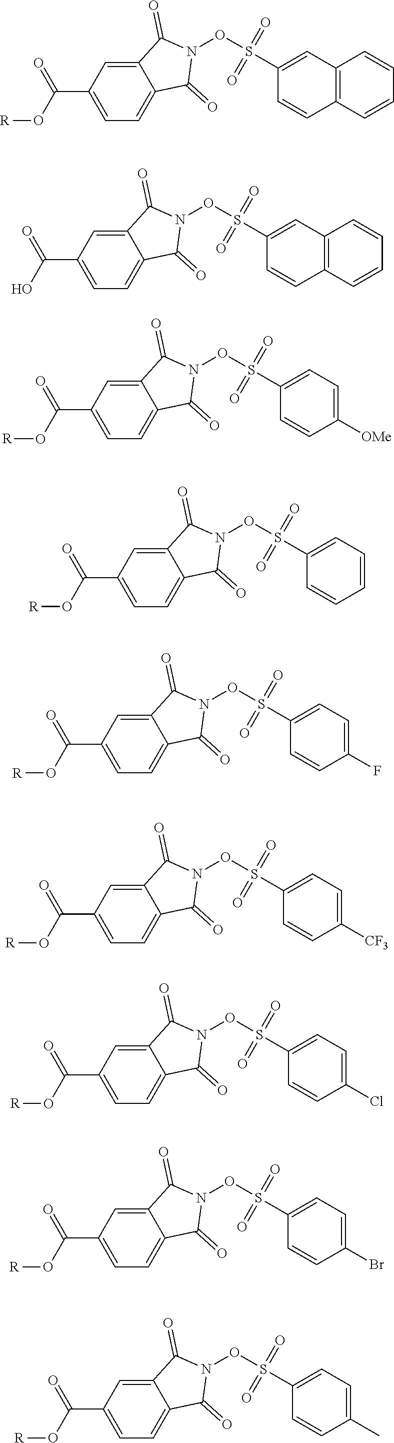

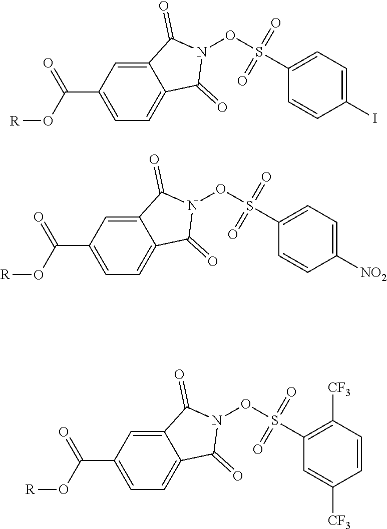

wherein R is a substituted or unsubstituted C₁₋₁₀ alkyl, or substituted or unsubstituted C₁₋₁₀ fluoroalkyl.

Typically, when the composition includes a non-polymeric PAG compound, the PAG compound is present in the composition in an amount of from 0.1 to 55 wt %, more typically 1 to 25 wt %, based on total solids of the photoresist composition. When present in polymeric form, the PAG compound is typically included in a polymer in an amount from 1 to 25 mol %, more typically from 1 to 8 mol %, or from 2 to 6 mol %, based on total repeating units in the polymer.

The photoresist composition further includes a solvent for dissolving the components of the composition and to facilitate its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane (DCM), 1,2-dichloroethane and 1-chlorohexane; alcohols such as methanol, ethanol, 1-propanol, iso-propanol, tert-butanol, 2-methyl-2-butanol, 4-methyl-2-pentanol, and diacetone alcohol (4-hydroxy-4-methyl-2-pentanone) (DAA); propylene glycol monomethyl ether (PGME); ethers such as diethyl ether, tetrahydrofuran, 1,4-dioxane, and anisole; ketones such as acetone, methyl ethyl ketone, methyl iso-butyl ketone, 2-heptanone, and cyclohexanone (CHO); esters such as ethyl acetate, n-butyl acetate, propylene glycol monomethyl ether acetate (PGMEA), ethyl lactate (EL), hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, and diphenyl carbonate; polar aprotic solvents such as dimethyl sulfoxide and dimethyl formamide; water; and combinations thereof. Of these, preferred solvents include one or more of PGME, PGMEA, EL, GBL, HBM, CHO, DAA, or a combination thereof.

The total solvent content (i.e., cumulative solvent content for all solvents) in the photoresist compositions is typically from 40 to 99 wt %, for example, from 60 to 99 wt %, or from 85 to 99 wt %, based on total solids of the composition. The desired solvent content will depend, for example, on the desired thickness of the coated (photoresist) layer and coating conditions.

Additionally, the compositions may further include one or more polymers in addition to and different from the polymer as described above. For example, the compositions may include an additional polymer as described above but different in composition. Additionally, or alternatively, the one or more additional polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The composition may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the compositions in an amount of from 0.01 to 20 wt %, based on total solids of the composition.

PDQs generate a relatively weak acid upon irradiation, such that the pKₐ of the acid generated by the PDQ is less than the pKₐ of the acid generated by the PAG. Exemplary photo-decomposable quenchers include, for example, photo-decomposable cations, and preferably those also useful for preparing strong acid generator compounds, paired with an anion of a weaker acid (pKₐ (PDQ)<pKₐ (PAG)) such as, for example, an anion of a C₁₋₂₀ carboxylic acid. Exemplary carboxylic acids include formic acid, acetic acid, propionic acid, tartaric acid, succinic acid, cyclohexanecarboxylic acid, benzoic acid, salicylic acid, and the like. In a preferred embodiment, the photo-decomposable quencher is a photo-decomposable organic zwitterion compound such as diphenyliodonium-2-carboxylate.

The PDQ may be in non-polymeric or polymer-bound form. The polymerized units containing the photo-decomposable quencher are typically present in an amount from 0.1 to 30 mol %, preferably from 1 to 10 mol % and more preferably from 1 to 2 mol %, based on total repeating units of the polymer. For example, the PDQ may be part of the second polymer, or may be part of an additional polymer. In some embodiments, the PDQ is not included in the first polymer.

Exemplary basic quenchers include, for example, linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, lutidine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher may be present in repeating units of the polymer. The repeating units containing the quencher are typically present in an amount of from 0.1 to 30 mole %, preferably from 1 to 10 mole % and more preferably from 1 to 2 mole %, based on total repeating units of the polymer. For example, the basic quencher may be part of the second polymer, or may be part of an additional polymer. In some embodiments, the basic quencher is not included in the first polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the composition further includes a surfactant polymer including a fluorine-containing repeating unit.

Patterning methods using the photoresist compositions of the invention will now be described. Suitable substrates on which the compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP™ 3000, AP™ 8000, and AP™ 9000S designations, available from DuPont Electronic Materials International, LLC (Marlborough, Massachusetts).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, from 1,000 to 2,500 rpm, for a period from 15 to 120 seconds to obtain a layer of the composition on the substrate. It will be appreciated by those skilled in the art that the thickness of the coated layer may be adjusted by changing the spin speed and/or the total solids of the composition. An EUV (photoresist) composition layer formed from the photoresist compositions of the invention typically has a dried layer thickness from 5 nm to 100 nm, preferably from greater than 10 nm to 80 nm, more preferably from 20 nm to 70 nm. An E-beam resist composition layer from the photoresist composition of the invention typically has a dried layer thickness from 50 nm to 3 m, preferably from greater than 70 nm to 1 m, more preferably from 100 nm to 500 nm.

The composition is typically next soft-baked to minimize the solvent content in the layer, thereby forming a tack-free coating and improving adhesion of the layer to the substrate. The soft bake is performed, for example, on a hotplate or in an oven, with a hotplate being typical. The soft bake temperature and time will depend, for example, on the composition and thickness. The soft bake temperature is typically from 70 to 170° C., and more typically from 80 to 140° C. The soft bake time is typically from 10 seconds to 20 minutes, more typically from 1 to 10 minutes, and still more typically from 30 s to 2 minutes. The heating time can be readily determined by one of ordinary skill in the art based on the ingredients of the composition.

The photoresist layer or E-beam resist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nm, sub-300 nm or sub-200 nm, with 248 nm (KrF), 193 nm (ArF), 13.5 nm (EUV) wavelengths or e-beam lithography being preferred. Preferably, the activating radiation is 248 nm radiation. The methods find use in immersion or dry (non-immersion) lithography techniques. The exposure energy is typically from 1 to 200 millijoules per square centimeter (mJ/cm²), preferably from 5 to 100 mJ/cm² and more preferably from 10 to 50 mJ/cm², dependent upon the exposure tool and components of the photoresist composition.

Following exposure of the photoresist layer, a post-exposure bake (PEB) of the exposed photoresist layer is performed. The PEB can be conducted, for example, on a hotplate or in an oven, with a hotplate being typical. Conditions for the PEB will depend, for example, on the photoresist composition and layer thickness. The PEB is typically conducted at a temperature from 70 to 150° C., preferably from 80 to 120° C., and a time from 30 to 120 seconds. A latent image defined by the polarity-switched (exposed regions) and unswitched regions (unexposed regions) is formed in the photoresist.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as TMAH, preferably 0.26 N TMAH, tetraethylammonium hydroxide, tetrabutylammonium hydroxide, or the like; or aqueous solutions of sodium hydroxide, potassium hydroxide, sodium carbonate, potassium carbonate, or the like. In some cases, suitable developers are organic solvent-based, meaning the cumulative content of organic solvents in the developer is 50 wt % or more, typically 95 wt % or more, 98 wt % or more, or 100 wt %, based on total weight of the developer. Suitable organic solvents for the developer include, for example, those chosen from ketones, esters, ethers, hydrocarbons, and mixtures thereof.

A coated substrate may be formed from the photoresist compositions of the invention. Such a coated substrate includes: (a) a substrate having one or more layers to be patterned on a surface thereof; and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The composition may also been used in other patterning process, such as a motif for self-aligned double patterning, or as matrix for vapor phase infiltration, area selective deposition, chemical vapor deposition, atomic layer vapor deposition, or molecular atomic layer deposition, before or after development. The compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following non-limiting examples.

### Examples

### Polymer Preparation:

The following polymers were used to prepare the formulations of the Examples.

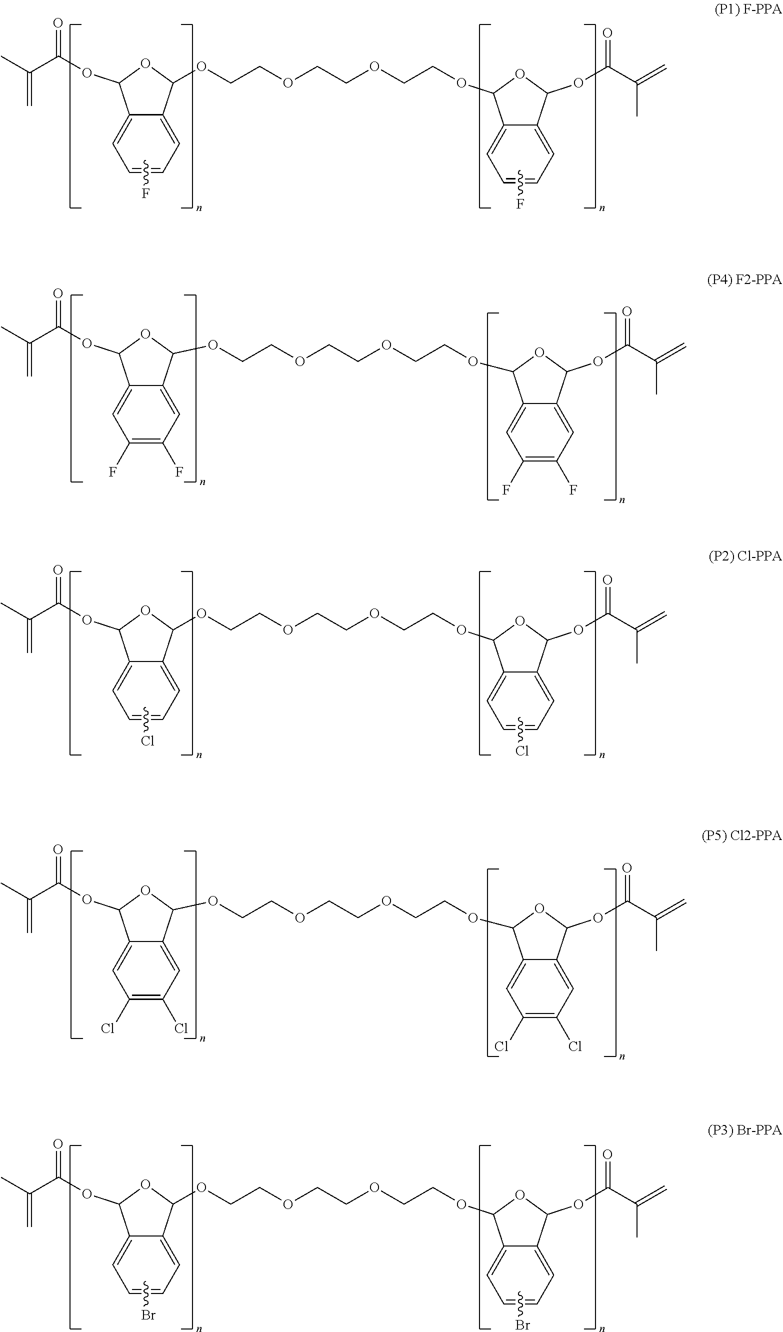

### General Polymerization Procedure for Polymerization Initiated by Triethylene Glycol

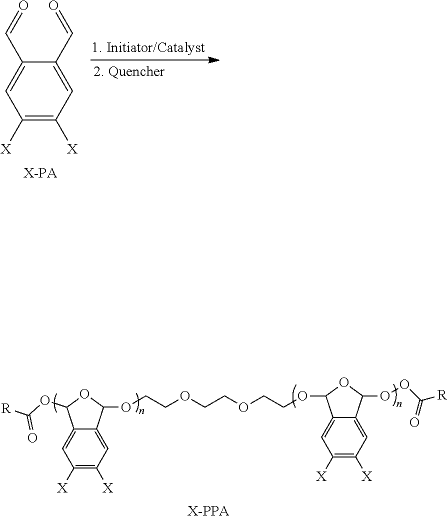

The respective X-PA monomer was substituted as defined in Table 1. Into a round-bottom flask (RBF), a solution of X-PA monomer in tetrahydrofuran (THF) (120 mL, 20 wt %) was combined with a solution of triethylene glycol in toluene (2 mL, 15 wt %). The flask was immersed into a dry ice/acetone bath on top of a magnetic stir plate. Using a dry syringe, a THF solution containing 1,8-diazobicyclo [5.4.0]undec-7-ene (DBU) (6 mL, 30 wt %) was quickly added into the mixture. After stirring for 4 hours, pivalic acid anhydride or methacrylic acid anhydride (6 mL) was added to quench the reaction. The volumes of monomer solution, triethylene glycol, and DBU were varied for different target molecular weights. The polymer was isolated by precipitation three times in methanol and once into heptanes before being dried under vacuum. After drying under vacuum at room temperature, the polymer was obtained. Molecular weight (MW) was determined using Gel Permeation Chromatography calibrated by polystyrene standards. It is noted that some chains were initiated from residual moisture in the reaction.

TABLE 1

| Polymer | X | X |
|---|---|---|
| P1 | H | F |
| P2 | H | Cl |
| P3 | H | Br |
| P4 | F | F |
| P5 | Cl | Cl |

The following photoacid generators B1-B4 were used to prepare photoresist compositions as described below.

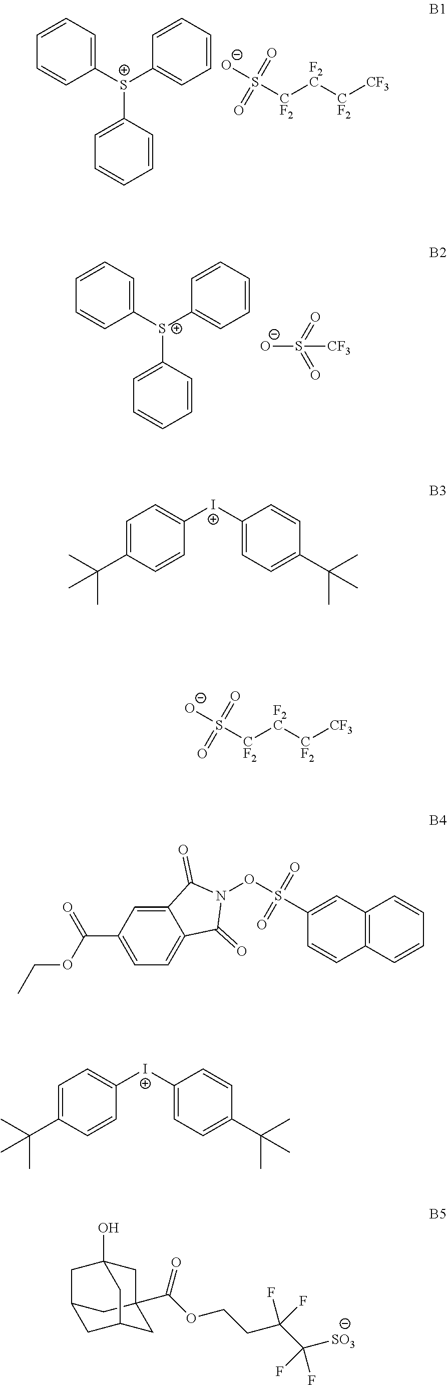

The following base quenchers or weak acid quencher C1-C2 were used to prepare photoresist compositions as described below.

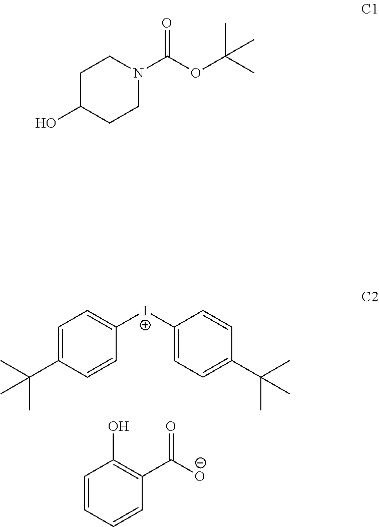

The following second polymer additives D1-D6 were used to prepare photoresist compositions as described below.

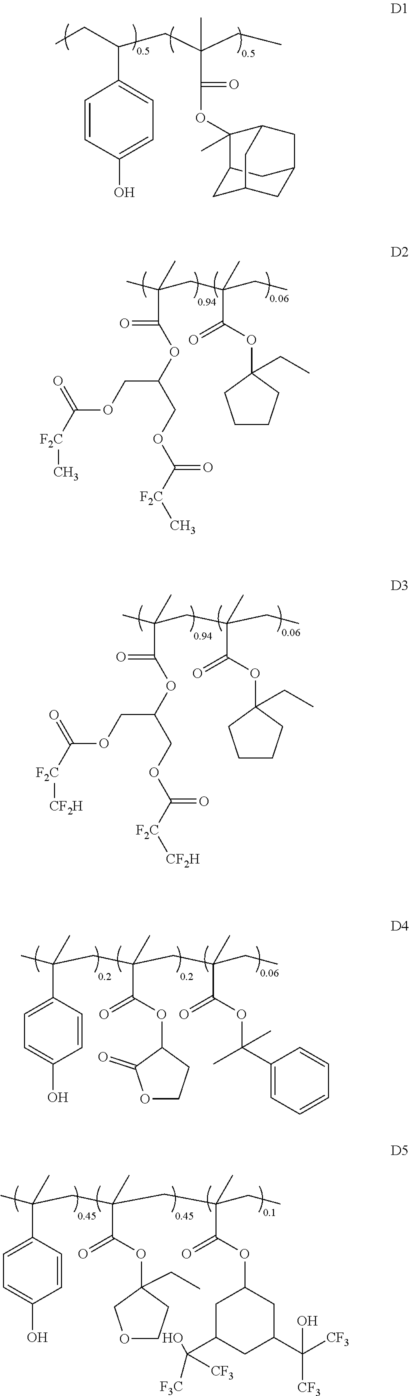

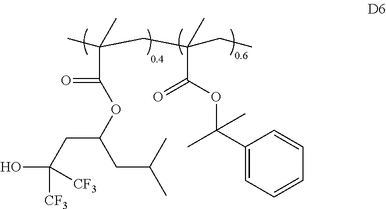

The following solvents S1-S3 were used to prepare photoresist compositions as described below. S1: PGMEA; S2: HBM; S3: Cyclohexanone.

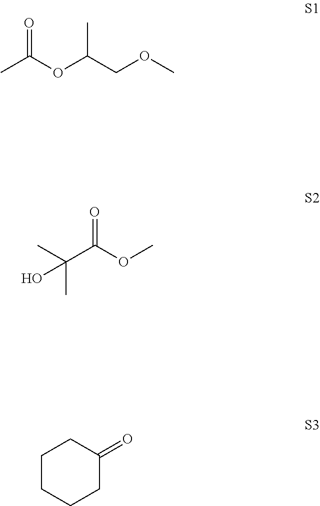

Photoresist compositions were formulated by combining the components shown in Table 2 in a given solvent system. Each mixture was filtered through a 0.2 μm PTFE disk prior to coating. The amounts included in Table 2 are wt % based on total weight of the solid components. The total solids content for each composition was 2.15 wt %.

TABLE 2

| | Photo- | | | | | |
|---|---|---|---|---|---|---|
| Ex | resist | Polymer 1 | PAG | Q1 | Polymer 2 | Solvent |
| Ex 1 | PR1 | P3 | B2 | C1 | D1 | S3 |
| | | [83.6] | [6.6] | [0.5] | [9.3] | |
| Ex 2 | PR2 | P3 | B2 | C1 | D1 | S3 |
| | | [9.3] | [6.6] | [0.5] | [83.6] | |
| Ex 3 | PR3 | P3 | B2 | C1 | D1 | S3 |
| | | [23.2] | [6.6] | [0.6] | [69.6] | |
| Ex 4 | PR4 | P3 | B2 | C1 | D1 | S3 |
| | | [23] | [6.6] | [1.3] | [69.1] | |
| Ex 5 | PR5 | P3 | B2 | C1 | D1 | S3 |
| | | [46.5] | [6.6] | [0.5] | [46.4] | |
| Ex 6 | PR6 | P3 | B2 | C1 | D1 | S3 |
| | | [20.4] | [13.2] | [5.1] | [61.3] | |
| Ex 7 | PR7 | P1 | B5 | C2 | D2 | S3 |
| | | [79] | [15] | [3.00] | [3.0] | |
| Ex 8 | PR8 | P2 | B5 | C2 | D2 | S3 |
| | | [79] | [15] | [3.00] | [3.0] | |
| Ex 9 | PR9 | P3 | B5 | C2 | D2 | S3 |
| | | [79] | [15] | [3.00] | [3.0] | |
| Ex 10 | PR10 | P4 | B5 | C2 | D2 | S3 |
| | | [79] | [15] | [3.00] | [3.0] | |
| Ex 11 | PR11 | P5 | B5 | C2 | D2 | S3 |
| | | [79] | [15] | [3.00] | [3.0] | |
| Ex 12 | PR12 | P3 | B1 | C2 | D2 | S3 |
| | | [79] | [15] | [3.00] | [3.0] | |
| Ex 13 | PR13 | P3 | B4 | C1 | D2 | S3 |
| | | [79] | [15] | [3.00] | [3.0] | |
| Ex 14 | PR14 | P3 | B3 | C2 | D2 | S3 |
| | | [79] | [15] | [3.00] | [3.0] | |
| Ex 15 | PR15 | P3 | B5 | C1 | D2 | S3 |
| | | [79] | [15] | [3.00] | [3.0] | |
| Ex 16 | PR16 | P3 | B5 | C2 | D1 | S3 |
| | | [79] | [15] | [3.00] | [3.0] | |
| Ex 17* | PR17 | P3 | B5 | C2 | None | S3 |
| | | [82] | [15] | [3.00] | | |
| Ex 18 | PR18 | P3 | B5 | C2 | D3 | S3 |
| | | [79] | [15] | [3.00] | [3.0] | |
| Ex 19 | PR19 | P3 | B5 | C2 | D4 | S3 |
| | | [62] | [15] | [3.00] | [20.0] | |
| Ex 20 | PR20 | P3 | B5 | C2 | D5 | S3 |
| | | [62] | [15] | [3.00] | [20.0] | |
| Ex 21 | PR21 | P3 | B5 | C2 | D6 | S3 |
| | | [62] | [15] | [3.00] | [20.0] | |
| Ex 22 | PR22 | P3 | B5 | C2 | [D1] | S3 |
| | | [59] | [15] | [3.00] | [23.0] | |

*denotes comparative example.

### Formulation Miscibility Evaluation

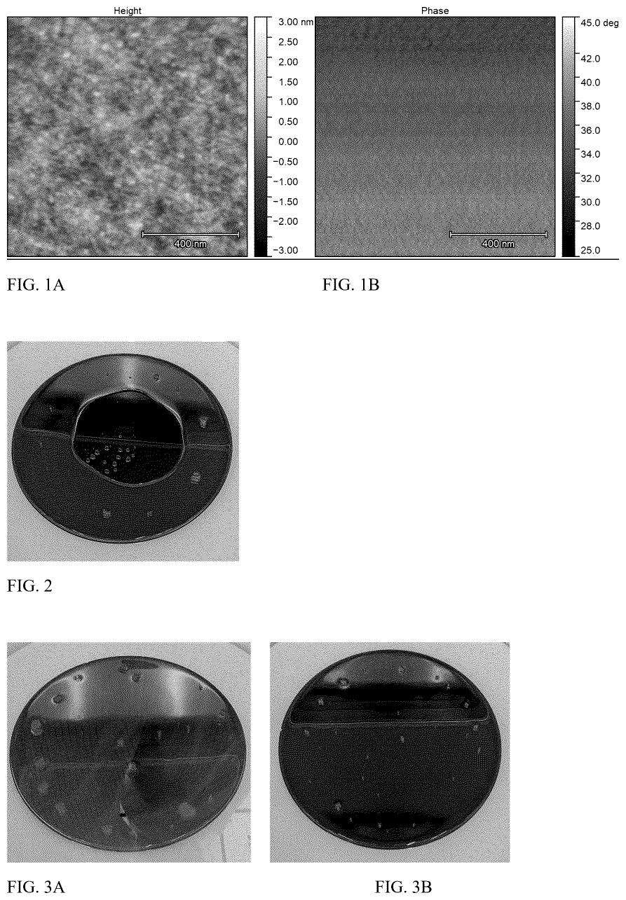

Example 5 was analyzed for miscibility using atomic force microscopy (AFM). A film of Example 5 was spin-coated onto a bare Si wafer to a film thickness of 50 nm. The film was soft baked at 80° C. for 60 s and the resultant film was analyzed using AFM on a Veeco Dimension 5000 tool in tapping mode. The cantilever model was Tap300AI-G, set to an f₀ value of 300 kHz and k-value of ~40 nN/nm. The scan size was 1 μm and the scan resolution was 512×512 with a pixel size of 2.0 nm. The resultant AFM gave Rq=0.3723 nm, suggesting the film of Example 5 had good miscibility between polymers P3 and D1, as shown in FIGS. 1A and 1B.

Wafer Dewet Evaluation with Aqueous TMAH Developer

FIG. 2 shows images of aqueous developer wettability issues for PPA photoresists that did not contain the second polymer (e.g., Example 17). Developer dispense onto high contact angle resist films resulted in pooling of aqueous developer during processing and non-uniform film quality in the resultant wafer.

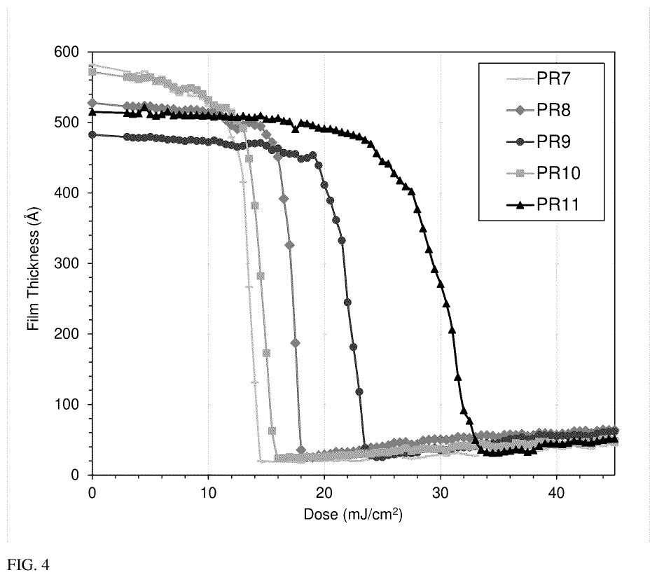

FIGS. 3A and 3B show images of improved aqueous developer wettability for PPA photoresists that include the second polymer (e.g., Examples 9 and 16).

Aqueous developer wettability was evaluated in part by visualizing the formation of the developer puddle on-track during Si wafer processing.

### KrF Evaluation Data

A given formulation was coated to a thickness of 50-60 nm on a 300 mm silicon wafer that was coated with AR™40A anti-reflectant (DuPont Electronic Materials International, LLC) using a cure temperature of 215° C. for 60 seconds to form a first BARC layer having a thickness of 800 Å. The wafers were soft baked at 100° C. for 60 seconds prior to exposure, then exposed at a given dose of KrF. After exposure, the wafers were subjected to a post-exposure bake at 90° C. for 60 seconds. The film was developed using an 2.38 wt % TMAH developer for 60 seconds and rinsed with DI water. Contrast curve thickness data was measured using a ThermaWave ellipsometer. The results are shown in Table 3.

TABLE 3

| Ex | PR | KrF E₀ (mJ/cm²) |
|---|---|---|
| Ex 1 | PR1 | 5 |
| Ex 2 | PR2 | 12.5 |
| Ex 3 | PR3 | 15 |
| Ex 4 | PR4 | 23.5 |
| Ex 5 | PR5 | 8.5 |
| Ex 6 | PR6 | 33.5 |
| Ex 7 | PR7 | 15 |
| Ex 8 | PR8 | 19 |
| Ex 9 | PR9 | 25 |
| Ex 10 | PR10 | 16.5 |
| Ex 11 | PR11 | 35 |
| Ex 12 | PR12 | 9 |
| Ex 13 | PR13 | 5 |
| Ex 14 | PR14 | 18 |
| Ex 15 | PR15 | 11.5 |
| Ex 16 | PR16 | 25.5 |
| Ex 17* | PR17 | 25 |
| Ex 18 | PR18 | 29 |
| Ex 19 | PR19 | 23 |
| Ex 20 | PR20 | 28.5 |
| Ex 21 | PR21 | 34.5 |
| Ex 22 | PR22 | 25.5 |

*denotes comparative example.

FIG. 4 shows KrF contrast curves of formulations prepared with identical PAG, PDQ, and Polymer 2 loadings but with different Polymer 1 derivatives (Examples 7, 8, 9, 10, and 11).

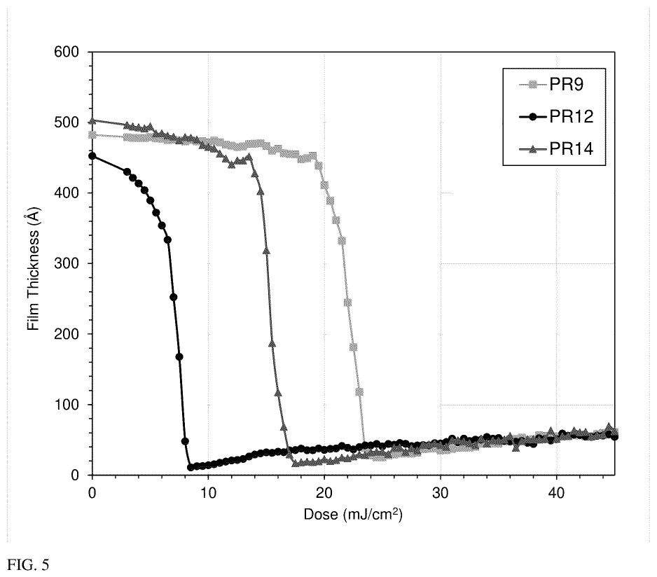

FIG. 5 shows KrF contrast curves of formulations prepared with identical Polymer 1, PDQ, and Polymer 2 component loadings but with different PAG compounds (Examples 9, 12, 14).

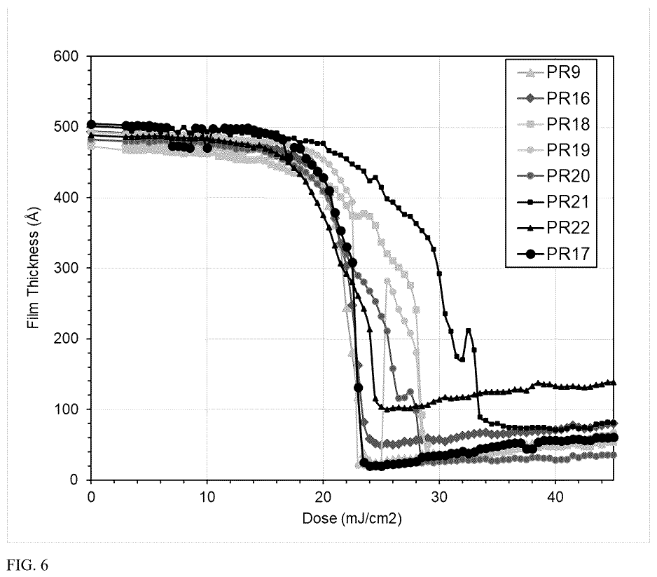

FIG. 6 shows KrF contrast curves of formulations prepared with identical Polymer 1, PAG, and PDQ components, but with different or no Polymer 2 (Examples 9, 16, 17, 18, 19, 20, 21, and 22). The variation in thickness measurement in PR17 is caused by the absence of a Polymer 2.

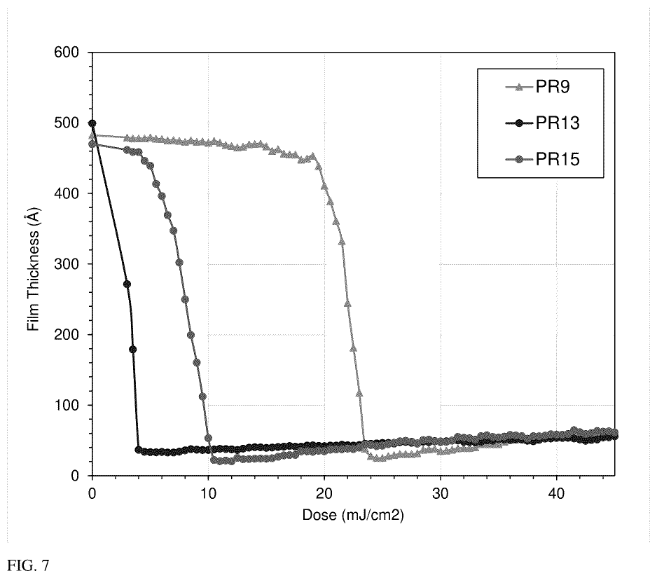

FIG. 7 shows KrF contrast curves of formulations prepared with identical Polymer 1, PAG, and PDQ components, but with different Polymer 2 additives (Examples 9, 13, and 15).

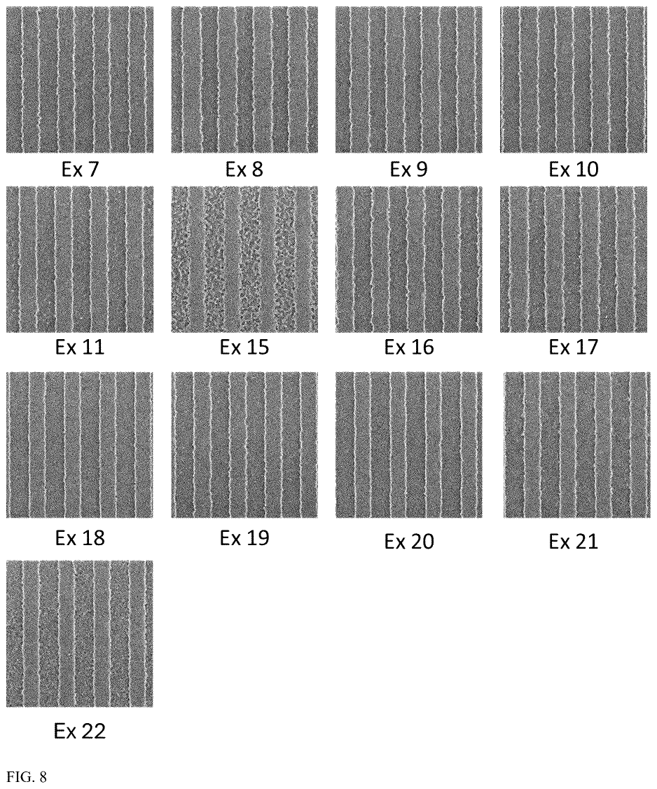

Patterned KrF images were taken using scanning electron microscopy (SEM) at 500 eV. FIG. 8 shows SEM images of Examples 7, 8, 9, 10, 11, 15, 16, and 17.

### EUV Contrast Curve Evaluation.

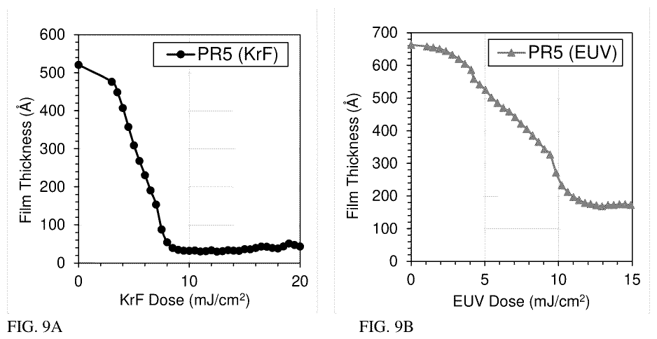

A thin film of Example 5 (PR5) was spin-coated onto an 8-inch silicon wafer using a TEL coating track by manually pipetting 1-2 mL of solvent on a wafer and spinning at 1000-2000 rpm to achieve a final film thickness of 55-65 nm. The film was baked at 110° C. for 60 seconds on a hot plate. Using a BEFORCE EUV flood exposure tool, which was built by EUV Tech and equipped with an Energetiq EQ-10 EUV source, a 4×11 grid was exposed to a 13.5 nm beam in 1 mJ increments beginning at 1 mJ/cm². The silicon wafer was then baked on a hot plate at 110° C. for 60 sec and developed with a puddle method using 2.38% tetramethylammonium hydroxide solution in water. Resultant film thickness was measured using an ellipsometer. FIG. 9A shows a KrF contrast curve of PR5 and FIG. 9B shows an EUV contrast curve of PR5.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photoresist composition, comprising:
a first polymer comprising a first repeating unit derived from a compound of Formula (1);
a second polymer comprising a first repeating unit comprising an acid-labile group, a base-labile group, a base soluble group, or a combination thereof, wherein the first repeating unit of the second polymer is derived from a monomer comprising an ethylenically unsaturated polymerizable double bond;
a photoacid generator; and
a solvent, 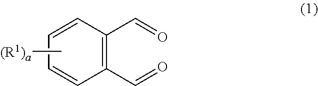
wherein, in Formula (1),
each R¹ is a non-hydrogen substituent,
each R¹ optionally further comprises one or more divalent linking groups as part of their structure, wherein each of the one or more divalent linking groups is independently substituted or unsubstituted,
two adjacent R¹ optionally form a ring together, wherein the ring is substituted or unsubstituted, and
a is an integer from 1 to 4.

2. The photoresist composition of claim 1, wherein each R¹ independently comprises fluorine, chlorine, bromine, iodine, nitrogen, oxygen, sulfur, or a combination thereof.

3. The photoresist composition of claim 1, wherein each R¹ is independently selected from fluorine, chlorine, bromine, iodine, nitro, cyano, hydroxyl, amino, mono- or di-(C₁₋₁₀)alkylamino, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₁₋₃₀ alkoxy, substituted or unsubstituted C₃₋₃₀ cycloalkyl, substituted or unsubstituted C₃₋₃₀ heterocycloalkyl, substituted or unsubstituted C₅₋₃₀ cycloalkenyl, substituted or unsubstituted C₂₋₃₀ heterocycloalkenyl, substituted or unsubstituted C₆₋₃₀ aryl, or substituted or unsubstituted C₃₋₃₀ heteroaryl.

4. The photoresist composition of claim 1, wherein the compound of Formula (1) is selected from: 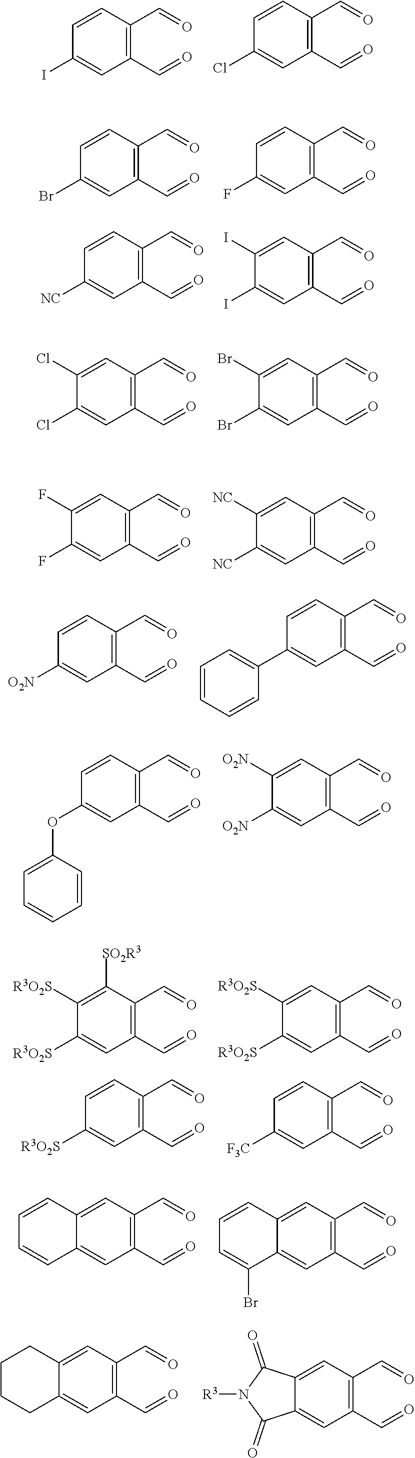
wherein,
R³ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl, and
two adjacent R³ optionally form a ring together, wherein the ring is substituted or unsubstituted.

5. The photoresist composition of claim 1, wherein the photoacid generator comprises an onium cation that is of Formula (15) or (16): 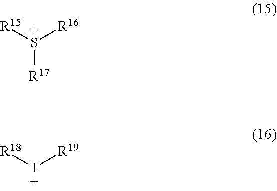
wherein, in Formulae (15) and (16),
each of R¹⁵ to R¹⁹ is independently substituted or unsubstituted C₁-20 alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, or substituted or unsubstituted C₄₋₂₀ heteroarylalkyl,
each of R¹⁵ to R¹⁹ optionally further comprises one or more divalent linking groups as part of their structure, wherein each of the one or more divalent linking groups is independently substituted or unsubstituted,
each of R¹⁵ to R¹⁷ is separate or connected to another group of R¹⁵ to R¹⁷ via a single bond or a divalent linking group, and
each of R¹⁸ to R¹⁹ is separate or connected to another group of R¹⁸ to R¹⁹ via a single bond or a divalent linking group.

6. The photoresist composition of claim 1, further comprising a second photoacid generator that is different from the photoacid generator, a photodecomposable quencher, a basic quencher, a surfactant, or a combination thereof.

7. The photoresist composition of claim 1, wherein the second polymer comprises the photoacid generator as part of its structure.

8. The photoresist composition of claim 1, wherein the first polymer further comprises a second repeating unit that is different from the first repeating unit, wherein the second repeating unit is derived from a compound of Formula (1).

9. A pattern forming method, comprising:
(a) applying a layer of the photoresist composition of claim 1 on a substrate;
(b) soft-baking the composition layer;
(c) exposing the soft-baked composition layer to activating radiation;
(d) post-exposure baking the composition layer; and
(e) developing the post-exposure baked composition layer using a developer to provide a resist relief image.

10. The method of claim 9, wherein the developer comprises an aqueous alkaline developer.

11. The method of claim 9, wherein the activating radiation is 248 nm (KrF), 193 nm (ArF), 13.5 nm (EUV), or e-beam lithography.

12. The method of claim 9, wherein each R¹ independently comprises fluorine, chlorine, bromine, iodine, nitrogen, oxygen, sulfur, or a combination thereof.

13. The method of claim 9, wherein each R¹ is independently selected from fluorine, chlorine, bromine, iodine, nitro, cyano, hydroxyl, amino, mono- or di-(C₁₋₁₀)alkylamino, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₁₋₃₀ alkoxy, substituted or unsubstituted C₃₋₃₀ cycloalkyl, substituted or unsubstituted C₃₋₃₀ heterocycloalkyl, substituted or unsubstituted C₅₋₃₀ cycloalkenyl, substituted or unsubstituted C₂₋₃₀ heterocycloalkenyl, substituted or unsubstituted C₆₋₃₀ aryl, or substituted or unsubstituted C₃₋₃₀ heteroaryl.

14. The method of claim 9, wherein the photoacid generator comprises an onium cation that is of Formula (15) or (16): 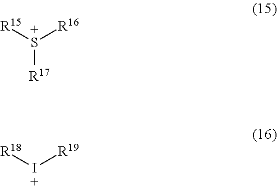
wherein, in Formulae (15) and (16),
each of R¹⁵ to R¹⁹ is independently substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₃₋₃₀ heteroaryl, substituted or unsubstituted C₇₋₂₀ arylalkyl, or substituted or unsubstituted C₄₋₂₀ heteroarylalkyl,
each of R¹⁵ to R¹⁹ optionally further comprises one or more divalent linking groups as part of their structure, wherein each of the one or more divalent linking groups is independently substituted or unsubstituted,
each of R¹⁵ to R¹⁷ is separate or connected to another group of R¹⁵ to R¹⁷ via a single bond or a divalent linking group, and
each of R¹⁸ to R¹⁹ is separate or connected to another group of R¹⁸ to R¹⁹ via a single bond or a divalent linking group.

15. The method of claim 9, further comprising a second photoacid generator that is different from the photoacid generator, a photodecomposable quencher, a basic quencher, a surfactant, or a combination thereof.

16. The method of claim 9, wherein the second polymer comprises the photoacid generator as part of its structure.

17. The method of claim 9, wherein the first polymer further comprises a second repeating unit that is different from the first repeating unit, wherein the second repeating unit is derived from a compound of Formula (1).
